(19) United States
(12) Patent Application Publication
(10) Pub. No.: US 2016/0260882 A1
(43) Pub. Date: Sep. 8, 2016

(54) THERMOELECTRIC CONVERSION MATERIAL, THERMOELECTRIC CONVERSION ELEMENT, ARTICLE FOR THERMOELECTRIC POWER GENERATION, AND POWER SOURCE FOR SENSOR

(71) Applicant: FUJIFILM Corporation, Tokyo (JP)

(72) Inventors: Ryo NISHIO, Ashigarakami-gun (JP); Kimiatsu NOMURA, Ashigarakami-gun (JP); Yoichi MARUYAMA, Ashigarakami-gun (JP)

(73) Assignee: FUJIFILM Corporation, Tokyo (JP)

(21) Appl. No.: 15/059,937

(22) Filed: Mar. 3, 2016

Related U.S. Application Data
(63) Continuation of application No. PCT/JP2014/072419, filed on Aug. 27, 2014.

(30) Foreign Application Priority Data
Sep. 4, 2013 (JP) 2013-183099

(51) Int. Cl. H01L 35/24; C08G 75/06; C08G 73/06; H01L 35/26

(52) U.S. Cl. CPC H01L 35/24; H01L 35/26; C08G 75/06; C08G 73/0611

(57) ABSTRACT

Provided are the following: a thermoelectric conversion element including, on a substrate, a first electrode, a thermoelectric conversion layer and a second electrode, in which the thermoelectric conversion layer contains an electroconductive nanomaterial having an average length in the major axis direction of at least 5 nm and a polymer compound having a repeating unit represented by the following Formula (1); an article for thermoelectric power generation and a power source for sensors, which use this thermoelectric conversion element; and a thermoelectric conversion material for forming the thermoelectric conversion layer, the thermoelectric conversion material containing the electroconductive nanomaterial described above and a polymer compound having a repeating unit represented by the following Formula (1).

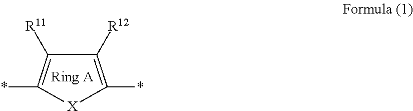

In Formula (1), ring A represents a conjugated hydrocarbon ring or a conjugated heterocyclic ring; X represents a group having one or two or more atoms selected from the group consisting of a carbon atom, an oxygen atom, a sulfur atom, a nitrogen atom, a phosphorus atom, and a silicon atom, shared as ring-constituting atoms of the ring A; the average inter-unit distance of the ring A is 1.42 Å or less; R¹¹ and R¹² each independently represent a substituent, and may be bonded to each other to form a ring; and the symbol * represents a bonding position for the repeating unit.

### CROSS-REFERENCE TO RELATED APPLICATIONS

This application is a Continuation of PCT International Application No. PCT/JP2014/072419 filed on Aug. 27, 2014, which claims priority under 35 U.S.C. §119 (a) to Japanese Patent Application No. 2013-183099 filed in Japan on Sep. 4, 2013. Each of the above applications is hereby expressly incorporated by reference, in its entirety, into the present application.

### BACKGROUND OF THE INVENTION

1. Field of the Invention

The present invention relates to a thermoelectric conversion material, a thermoelectric conversion element, and an article for thermoelectric power generation and a power source for sensors, which use this thermoelectric conversion element.

2. Description of the Related Art

Thermoelectric conversion materials that can convert between heat energy and electrical energy are used in thermoelectric power generating elements or thermoelectric conversion elements such as Peltier devices. Thermoelectric power generation achieved by applying such thermoelectric conversion materials or thermoelectric conversion elements enables direct conversion from heat energy to electric power, does not require any moving parts, and are used in wristwatches that are operated by body temperature, as well as power supplies for remote areas and power supplies used in space.

Thermoelectric power generation makes use of a thermoelectric conversion element (also called a thermoelectric power generation element) produced using a thermoelectric conversion material that can convert between heat energy and electrical energy. Known examples of thermoelectric conversion materials include inorganic thermoelectric conversion materials and organic thermoelectric conversion materials, and in recent years, materials using carbon nanotubes and the like have also been attracting attention.

Regarding such a material, although not related to thermoelectric conversion elements, for example, a semiconductor-like material based on polymers of at least two kinds (see, for example, JP2011-522422A in connection with the inclusion of a polymer and a filler material), and nanotubes or nanowires containing a light-emitting polymer having a π-conjugated structure (JP2010-508387A) may be mentioned.

### SUMMARY OF THE INVENTION

However, even if thermoelectric conversion elements are produced using the materials described in JP2011-522422A and JP2010-508387A, the thermoelectric conversion performance and the dispersibility of electrically conductive nanomaterials are not sufficient, and there is room for further improvement.

An object of the present invention is to provide a thermoelectric conversion material which exhibits high dispersibility of an electroconductive nanomaterial and exhibits superior thermoelectric conversion performance, a thermoelectric conversion element, and an article for thermoelectric power generation and a power source for sensors, which use this thermoelectric conversion element.

The inventors of the present invention paid attention to the structure, properties and the like of conjugated rings that form the main chain of a polymer compound, and conducted an investigation. Thus, the inventors found that a polymer compound in which conjugated rings that form the main chain are bonded with a particular bonding distance therebetween, exhibits excellent thermoelectric conversion performance when the polymer compound is co-present with an electroconductive nanomaterial having a particular size. Furthermore, the inventors found that this polymer compound exhibits a strong interaction with the electroconductive nanomaterial, and increases the dispersibility of the electroconductive nanomaterial. Thus, the invention was completed based on these findings.

That is, the object described above was achieved by the following means.

<1> A thermoelectric conversion element including, on a substrate, a first electrode, a thermoelectric conversion layer, and a second electrode, in which the thermoelectric conversion layer contains an electroconductive nanomaterial having an average length in the major axis direction of at least 5 nm, and a polymer compound having a repeating unit represented by the following Formula (1).

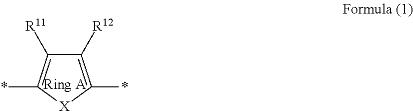

In Formula (1), ring A represents a conjugated hydrocarbon ring or a conjugated heterocyclic ring; X represents a group having one or two or more atoms selected from the group consisting of a carbon atom, an oxygen atom, a sulfur atom, a nitrogen atom, a phosphorus atom and a silicon atom, shared as ring-constituting atoms of the ring A; the average inter-unit distance of the ring A is 1.42 Å or less; R¹¹ and R¹² each independently represent a substituent, and may be bonded to each other to form a ring; and the symbol * represents a bonding position for the repeating unit.

<2> The thermoelectric conversion element according to <1>, in which the polymer compound has a repeating unit represented by the following Formula (2).

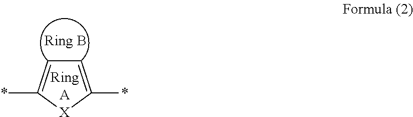

In Formula (2), ring B represents an aromatic ring; ring 1 may have a substituent, and may also have an aromatic hydrocarbon ring or an aromatic heterocyclic ring fused thereto; rings A and X have the same meanings as the rings A and X of Formula (1); the average inter-unit distance of the ring A is 1.42 Å or less; and the symbol * represents a bonding position for the repeating unit.

<3> The thermoelectric conversion element according to <1> or <2>, in which the ring structure of the ring A is a ring structure represented by any one of the following Formulae (3) to (8).

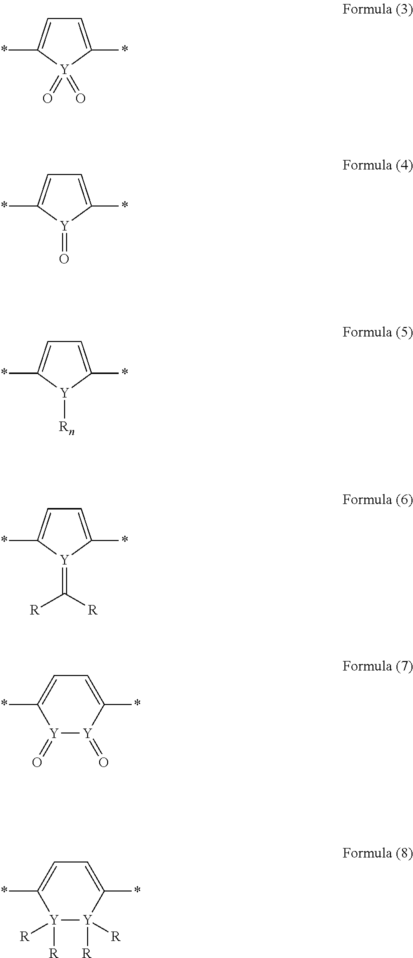

In Formulae (3) to (8), each Y independently represents an atom selected from the group consisting of a carbon atom, a sulfur atom, a nitrogen atom, a phosphorus atom, and a silicon atom, two Y's in Formulae (7) and (8) may be identical or different: n represents an integer of 1 or more: R represents an alkyl group or an aryl group; in a case in which n represents an integer of 2 or more in Formula (5), and in the case of Formula (6) and Formula (8), plural R's may be identical or different; and the symbol * represents a bonding position for the repeating unit.

<4> The thermoelectric conversion element according to <2> or <3>, in which the ring B represents a benzene ring or a 5-membered or 6-membered aromatic heterocyclic ring.

<5> The thermoelectric conversion element according to any one of <1> to <4>, in which the polymer compound has at least one repeating unit selected from the group consisting of an ethenylene group, an ethynylene group, an arylene group, and a heteroarylene group.

<6> The thermoelectric conversion element according to any one of <1> to <5>, in which the thermoelectric conversion layer contains at least one polymer binder selected from a conjugated polymer binder and a non-conjugated polymer binder.

<7> The thermoelectric conversion element according to any one of <1> to <6>, in which the electroconductive nanomaterial is a carbon nanomaterial or a metal nanomaterial.

<8> The thermoelectric conversion element according to any one of <1> to <7>, in which the electroconductive nanomaterial is at least one material selected from the group consisting of carbon nanotubes, carbon nanofibers, graphite, graphene, carbon nanoparticles, and metal nanowires.

<9> The thermoelectric conversion element according to any one of <1> to <8>, in which the electroconductive nanomaterial is the carbon nanotube.

<10> The thermoelectric conversion element according to any one of <1> to <9>, in which the thermoelectric conversion layer contains a dopant.

<11> The thermoelectric conversion element according to any one of <1> to <10>, in which the substrate has flexibility.

<12> The thermoelectric conversion element according to any one of <1> to <1>, in which the first electrode and the second electrode are each independently formed from aluminum, gold, silver, or copper.

<13> An article for thermoelectric power generation, using the thermoelectric conversion element according to any one of <1> to <12>.

<14> A power source for sensors, using the thermoelectric conversion element according to any one of <1> to <12>.

<15> A thermoelectric conversion material for forming a thermoelectric conversion layer of a thermoelectric conversion element, in which the thermoelectric conversion material includes an electroconductive nanomaterial having an average length in the major axis direction of at least 5 nm, and a polymer compound having a repeating unit represented by the following Formula (1).

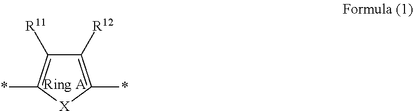

In Formula (1), ring A represents a conjugated hydrocarbon ring or a conjugated heterocyclic ring; X represents a group having one or two or more atoms selected from the group consisting of a carbon atom, an oxygen atom, a sulfur atom, a nitrogen atom, a phosphorus atom and a silicon atom, shared as ring-constituting atoms of the ring A; the average inter-unit distance of the ring A is 1.42 Å or less; R¹¹ and R¹² each independently represent a substituent, and may be bonded to each other to form a ring; and the symbol * represents a bonding position for the repeating unit.

<16> The thermoelectric conversion material according to <15>, in which the polymer compound has a repeating unit represented by the following Formula (2).

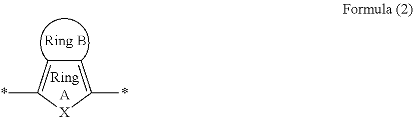

In Formula (2), ring B represents an aromatic ring; ring B may have a substituent, or may have an aromatic hydrocarbon ring or an aromatic heterocyclic ring fused thereto; rings A and X have the same meanings as the rings A and X of Formula (1), the average inter-unit distance of the ring A is 1.42 Å or less; and the symbol * represents a bonding position for the repeating unit.

<17> The thermoelectric conversion material according to <16>, in which the ring 13 represents a benzene ring or a 5-membered or 6-membered aromatic heterocyclic ring.

<18> The thermoelectric conversion material according to any one of <15> to <17>, containing at least one polymer binder selected from a conjugated polymer binder and a non-conjugated polymer binder.

<19> The thermoelectric conversion material according to any one of <15> to <18>, containing an organic solvent.

<20> The thermoelectric conversion material according to <19>, obtained by dispersing an electroconductive nanomaterial in the organic solvent.

According to the invention, a polymer compound refers to a compound that is excited by heat, in which repeating units each having a ring with an average inter-unit distance of 1.42 Å or less are incorporated in to the main chain via this ring.

According to the invention, the average inter-unit distance L of the ring A refers to an average distance of interatomic distances L1 and L2, each interatomic distance being a distance between a ring-constituting atom to which a direct bond forming the main chain of the repeating unit represented by Formula (1) is directly bonded, and an adjacent atom of the main chain to which this ring-constituting atom is directly bonded by the direct bond.

Specifically, the average inter-unit distance can be determined by the following Formula (1), from the interatomic distances L1 and L2.

Average inter-unit distance L=(interatomic distance L1+interatomic distance L2)/2 Formula (1):

At this time, the repeating unit that is directly bonded to the repeating unit represented by Formula (1) is not particularly limited as long as the repeating unit can form a conjugated system of the main chain, as will be described below. For example, ethenylene groups are shown in examples 2 and 3 described below.

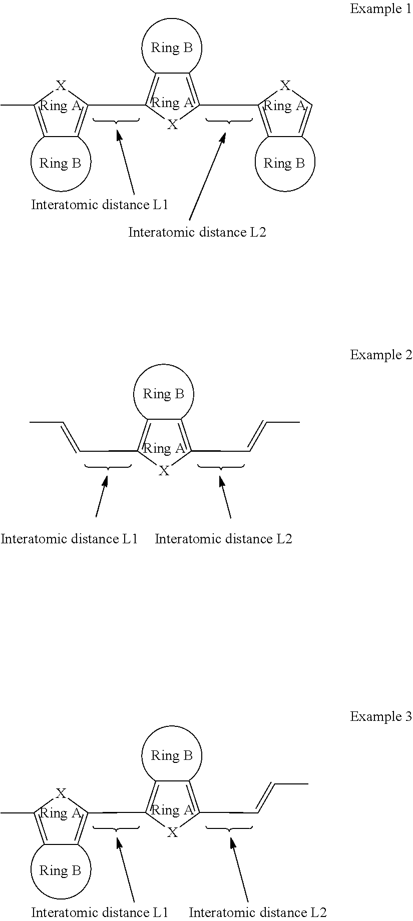

As this average inter-unit distance L becomes shorter, the double bond character of the bond between atoms that are directly bonded by the direct bond of the ring A is enhanced, and it becomes easier for the ring A to form a pseudo-quinoid type resonant structure that will be described below.

According to the present invention, the contribution ratio of the pseudo-quinoid type resonant structure is defined by the interatomic distance L of a direct bond of the ring A.

These interatomic distances L1 and L2 (unit: Å) can be calculated from an optimized structure, by the Gaussian calculation method (name of program used: (GAUSSIAN 09 (manufactured by Gaussian, Inc.), parameter used: B3LYP/6-31 G*). Meanwhile, in order to calculate by computation the interatomic distance which reflects the main chain conjugated structure of the polymer compound, it is necessary to have a conjugation length of a sufficient length as a molecular structure for calculation input, that is, to have a sufficient number of repeating units. Specifically, it is necessary that at least four repeating units are linked on either side of the bond with which the interatomic distance L1 or L2 is calculated as the structure for calculation input. According to the invention, the interatomic distance L1 or L2 represents the calculated value in a case in which the number of linked repeating units is “eight in total”.

According to the invention, a value range indicated using the symbol “˜” means a range including the values described before and after the symbol “˜” as the lower limit value and the upper limit value.

Furthermore, according to the invention, when a “xxx group” is mentioned in relation to a substituent, the xxx group may have an optional substituent. Furthermore, when there are a number of groups represented by the same reference characters, the groups may be identical to or different from each other.

A repeating structure represented by each formula is intended to include different repeating structures as long as the structures are included in the scope represented by the formula, even if the repeating structures are not perfectly identical. For example, in a case in which repeating structures have an alkyl group as a substituent, the repeating structures represented by each formula may be composed only of a repeating structure having a methyl group, or the repeating structures may include a repeating structure having another alkyl group, for example, an ethyl group, in addition to the repeating structure having a methyl group.

The thermoelectric conversion material and the thermoelectric conversion element of the invention exhibit high dispersibility of an electroconductive nanomaterial, and exhibit excellent thermoelectric conversion performance.

Furthermore, the article for thermoelectric power generation and the power source for sensors of the invention, which use the thermoelectric conversion element of the invention, exhibit excellent thermoelectric conversion performance.

The above-described features and advantages and other features and advantages of the invention will be made clearer from the following descriptions and the attached drawings.

### BRIEF DESCRIPTION OF THE DRAWINGS

FIG. 1 is a diagram schematically illustrating a cross-section of an example of the thermoelectric conversion element of the invention. The arrow in FIG. 1 indicates the direction of the temperature difference applied at the time of use of the element.

FIG. 2 is a diagram schematically illustrating a cross-section of another example of the thermoelectric conversion element of the invention. The arrow in FIG. 2 indicates the direction of the temperature difference applied at the time of use of the element.

### DESCRIPTION OF THE PREFERRED EMBODIMENTS

The thermoelectric conversion element of the invention has a first electrode, a thermoelectric conversion layer, and a second electrode on a substrate. This thermoelectric conversion layer contains an electroconductive nanomaterial having an average length in the major axis direction of at least 5 nm, and a polymer compound having a repeating unit represented by Formula (1) described above (polymer compound of the invention). This thermoelectric conversion layer is formed on a substrate using the thermoelectric conversion material of the invention containing the electroconductive nanomaterial and the polymer compound of the invention described above.

The thermoelectric conversion performance of the thermoelectric conversion element of the invention can be expressed by a dimensionless figure of merit ZT (hereinafter, may be simply referred to as figure of merit ZT) represented by the following Formula (A):

Figure of merit ZT=S²·σ·T/κ Formula (A)

In Formula (A), S (V/K): Thermoelectromotive force per an absolute temperature of 1 K (Seebeck coefficient)
σ (S/nm): Electrical conductivity
κ (W/mK): Thermal conductivity
T (K): Absolute temperature

As is obvious from Formula (A) described above, in order to achieve an enhancement of the thermoelectric conversion performance, it is important to increase the thermoelectromotive force S and the electrical conductivity σ, and to decrease the thermal conductivity κ at the same time. As such, since factors other than the electrical conductivity σ have significant influence on the thermoelectric conversion performance, even if a material which is generally considered to have a high electrical conductivity σ is used, it is actually unknown whether the material would efficiently function as a thermoelectric conversion material.

Furthermore, a thermoelectric conversion element functions, in a state of having a temperature difference generated in the thickness direction or in the planar direction of the thermoelectric conversion layer, so as to transfer the temperature difference in the thickness direction or the planar direction. Therefore, it is necessary to form a thermoelectric conversion layer by forming a thermoelectric conversion material into a shape having a certain degree of thickness. Accordingly, in a case in which a thermoelectric conversion layer is formed by coating, the thermoelectric conversion material is required to have satisfactory coatability or film-forming properties. The thermoelectric conversion material of the invention has satisfactory dispersibility of an electroconductive nanomaterial and has excellent coatability or film-forming properties, so that the thermoelectric conversion material is adequate for forming and processing into a thermoelectric conversion layer.

The thermoelectric conversion material of the invention, as well as the thermoelectric conversion element and the like of the invention, will be explained below.

[Thermoelectric Conversion Material]

The thermoelectric conversion material of the invention is a thermoelectric conversion composition for forming a thermoelectric conversion layer of a thermoelectric conversion element, and contains an electroconductive nanomaterial having an average length in the major axis direction of at least 5 nm, and the polymer compound of the invention described above.

First, the various components used in the thermoelectric conversion material of the invention will be described.

<Electroconductive Nanomaterial>

The electroconductive nanomaterial used for the invention may be any material having electrically conductive properties and having an average length in the major axis direction of at least 5 nm. The term “nano” means nanometer.

The average length in the major axis direction refers to the average of lengths in the major axis direction in a non-aggregate (for example, referring to a non-aggregated state, such as primary particles or individual molecules) of an electroconductive nanomaterial. This average length can be determined by measuring the lengths in the major axis direction of thirty electroconductive nanomaterials by means of an image analysis such as transmission electron microscopy (TEM), scanning electron microscopy (SEM), scanning tunneling microscopy (STM), or atomic force microscopy (AFM), and calculating the average of these lengths.

The average length in the major axis direction is not particularly limited as long as it is at least 5 nm, and for example, the average length is preferably 1000 μm or less, and more preferably 500 μm or less.

When the average length in the major axis direction of the electroconductive nanomaterial is large as such, dispersibility thereof is increased by the thermally excitable polymer of the invention, which will be described below. It is speculated that a large electroconductive nanomaterial having an average length in the major axis direction of at least 5 nm readily undergoes an intermolecular interaction such as a π-π interaction with the thermally excitable polymer of the invention.

Examples of the electroconductive nanomaterial used for the invention include carbon materials (hereinafter, may be referred to as carbon nanomaterials) and metal materials (hereinafter, metal nanomaterials), which have electrically conductive properties.

Among the carbon nanomaterials and the metal nanomaterials, preferred examples of the electroconductive nanomaterial include carbon nanomaterials such as carbon nanotubes (hereinafter, also referred to as CNT), carbon nanofibers, graphite, graphene, and carbon nanoparticles; and metal nanowires, and from the viewpoint of enhancing the electrically conductive properties and enhancing the dispersibility in a solvent, carbon nanotubes are particularly preferred.

The content of the electroconductive nanomaterial in the thermoelectric conversion material is preferably 2% by mass to 60% by mass, more preferably 5% by mass to 55% by mass, and particularly preferably 10% by mass to 50% by mass, relative to the total solid content of the thermoelectric conversion material, from the viewpoint of the thermoelectric conversion performance.

The electroconductive nanomaterials may be used singly, or in combination of two or more kinds thereof. In a case in which two or more kinds of electroconductive nanomaterial are used in combination, at least one kind each of carbon nanomaterials and metal nanomaterials may be used in combination, or two kinds of carbon nanomaterial or two kinds of metal nanomaterial may be used in combination.

1. Carbon Nanomaterial

The carbon nanomaterial used for the invention is a carbon material having electrically conductive properties and having the above-mentioned average length, and an example thereof is an electroconductive material in which carbon atoms are chemically bonded by a carbon-carbon bond formed from the sp² hybrid orbitals of carbon atoms. Specific examples thereof include carbon nanotubes, carbon nanohorns having a form of a carbon nanotube with one end closed, carbon nanofibers, carbon nanowalls, carbon nanofilaments, carbon nanocoils, vapor grown carbon fibers (VGCF), graphite, graphene, carbon nanoparticles, and a cup-shaped carbon nanomaterial having an opening at the head of a carbon nanotube. Furthermore, various carbon blacks exhibiting electrically conductive properties, which have a graphite type crystal structure, can also be used as the carbon nanomaterial. Examples thereof include Ketjen black and acetylene black, and specific examples include carbon black under the trade name “VULCAN” manufactured by Cabot Corp.

The carbon nanomaterial used for the invention is not particularly limited as long as the nanomaterial has an average length in the major axis of at least 5 nm. Specifically, when the carbon nanomaterial is composed of carbon nanotubes, carbon nanohorns, carbon nanofibers, carbon nanofilaments, carbon nanocoils, vapor grown carbon fibers (VGCF), or a cup-shaped carbon nanomaterial, and particularly when the carbon nanomaterial is CNT, the average length in the major axis direction is preferably 0.01 μm to 1000 μm, and more preferably 0.1 μm to 100 μm, from the viewpoints of the ease of production, film forming properties, electrically conductive properties, and the like. Furthermore, the average diameter is not particularly limited; however, from the viewpoints of durability, transparency, film forming properties, electrically conductive properties, and the like, the average diameter is preferably 0.4 nm to 100 nm, more preferably 50 nm or less, and even more preferably 15 nm or less.

In regard to carbon nanowalls, graphite, and graphene, it is desirable that the average length in the major axis direction, that is, the average length of one side, is at least 5 nm. The upper limit thereof is not particularly limited; however, for example, the upper limit is preferably 80 μm.

In regard to carbon nanoparticles, it is desirable that the average particle size as the average length in the major axis direction is at least 5 nm. The upper limit thereof is not particularly limited; however, for example, the upper limit is preferably 200 nm.

Among those materials described above, preferred examples of the carbon nanomaterial include carbon nanotubes, carbon nanofibers, graphite, graphene, and carbon nanoparticles, and carbon nanotubes are particularly preferred.

These carbon nanomaterials can be produced by conventional production methods. Specific examples thereof include catalytic hydrogen reduction of carbon dioxide, an arc discharge method, a laser evaporation method, a chemical vapor phase epitaxy method (hereinafter, referred to as CVD method), a vapor phase epitaxy method, a vapor phase flow method, a HiPco method of causing carbon monoxide to react by high temperature pressurization with an iron catalyst and thereby growing a carbon material in the vapor phase, and an oil furnace method. Carbon nanomaterials produced as such can be used without further processing, or can be used after being purified by washing, centrifugation, filtration, oxidation, chromatography or the like. Furthermore, if necessary, carbon nanomaterials that have been pulverized using bowl type kneading apparatuses and the like such as a ball mill, a vibration mill, a sand mill, and a roll mill; carbon nanomaterials that have been cut short by chemical and physical treatments; and the like can also be used.

Carbon nanotubes will be explained below. Examples of CNTs include single wall CNTs composed of a single sheet of carbon film (graphene sheet) wound into a cylindrical form; bilayer CNTs composed of two sheets of graphene sheets wound into a concentric form; and multiwall CNTs composed of plural sheets of graphene sheets wound into a concentric form. According to the invention, single wall CNTs, bilayer CNTs, and multiwall CNTs may be used singly, or two or more kinds thereof may be used together. Particularly, it is preferable to use single wall CNTs and bilayer CNTs, which have excellent properties in connection with electrically conductive properties and semiconductor characteristics, and it is more preferable to use single wall CNTs.

In the case of single wall CNTs, the symmetry of a spiral structure based on the direction of hexagons of graphene of a graphene sheet is referred to as axial chirality, and a two-dimensional lattice vector from a reference point of a 6-membered ring on the graphene is referred to as a chiral vector. This chiral vector is converted into an index (n, m), which is called a chirality index, and materials are divided into metallic materials and semiconductor-like materials based on this chirality index. Specifically, when the value of (n−m) is a multiple of 3, the material exhibits metallic properties, and when the value is not a multiple of 3, the material exhibits semiconductor-like properties.

The single wall CNTs used for the invention may be semiconductor-like CNTs, or may be metallic CNTs, and it is also acceptable to use both. Also, the CNTs may contain metal atoms and the like.

CNTs can be produced by an arc discharge method, a CVD method, a laser abrasion method, or the like. The CNTs used for the invention may be a product obtained by any arbitrary method, and preferred examples thereof include products obtained by an arc discharge method and CVD method.

When CNTs are produced, fullerene, graphite or non-crystalline carbon may be simultaneously produced as a side product. The CNTs may be purified in order to remove these side products. The method for purifying CNTs is not particularly limited; however, in addition to the purification methods described above, an acid treatment using nitric acid, sulfuric acid or the like, and an ultrasonication treatment are effective for the removal of impurities. In addition, it is more preferable to perform separation and removal using a filter, from the viewpoint of increasing purity.

After purification, the CNTs thus obtained may be used without further processing. Furthermore, since CNTs can be generally obtained in the form of string, the CNTs may be used after being cut to a desired length according to the use. CNTs can be cut into a short fiber form by an acid treatment using nitric acid, sulfuric acid or the like, an ultrasonication treatment, a freeze grinding method, or the like. Also, it is also preferable to perform separation using a filter, from the viewpoint of increasing purity.

According to the invention, not only cut CNTs but CNTs that have been produced in a short fiber form in advance can also be used similarly. Such short fiber-shaped CNTs are obtained in the form of being oriented in a vertical direction on the surface of a substrate by, for example, forming a catalytic metal such as iron or cobalt on the substrate, thermally decomposing a carbon compound on the surface of the catalytic metal at 700° C. to 900° C. by a CVD method, and thereby growing CNTs in the vapor phase. The short fiber-shaped CNTs produced as such can be taken out by a method of stripping off the CNTs from the substrate, or the like. Furthermore, short fiber-shaped CNTs can also be obtained by supporting a catalytic metal on a porous support such as porous silicon or an anodic oxide film of alumina, and growing CNTs on the surface of the catalytic metal by a CVD method. Oriented short fiber-shaped CNTs can also be produced by a method of producing CNTs on a substrate by using molecules such as iron phthalocyanine containing catalytic metal in the molecule as a raw material, and performing CVD in a gas stream of argon/hydrogen. Furthermore, short fiber-shaped CNTs oriented on the surface of a SiC single crystal can also be obtained by an epitaxial growth method.

2. Metal Nanomaterial

The metal nanomaterial used for the invention is a fibrous or particulate metal material having the aforementioned average length. Specific examples thereof include fibrous metal materials (also called metal fibers) and particulate metal materials (also called metal nanoparticles). The metal nanomaterial is preferably composed of metal nanowires that will be described below.

It is preferable that metal fibers have a solid structure or a hollow structure. It is desirable that the metal fibers used for the invention have an average length in the major axis of at least 5 nm. Among metal fibers, metal fibers having a solid structure with an average length in the minor axis direction of 1 nm to 1,000 nm and an average length in the major axis direction of 1 μm to 100 μm are called metal nanowires, and metal fibers having a hollow structure with an average length in the minor axis direction of 1 nm to 1,000 nm and an average length in the major axis direction of 0.1 μm to 1,000 μm are called metal nanotubes.

The material of metal fibers may be any metal having electrically conductive properties, and the material can be appropriately selected according to the purpose. The material of the metal fibers is preferably, for example, at least one metal selected from the group consisting of the elements of Period 4, Period 5, and Period 6 of the Long-Form Periodic Table (International Union of Pure and Applied Chemistry (IUPAC), revised in 1991); more preferably at least one metal selected from Group 2 to Group 14; and even more preferably at least one metal selected from Group 2, Group 8, Group 9, Group 10, Group 11, Group 12, Group 13, and Group 14.

Examples of such a metal include copper, silver, gold, platinum, palladium, nickel, tin, cobalt, rhodium, iridium, iron, ruthenium, osmium, manganese, molybdenum, tungsten, niobium, tantalum, titanium, bismuth, antimony, lead, and alloys thereof. Among these, silver and alloys of silver are preferred from the viewpoint of having excellent electrically conductive properties. Examples of the metal used in the alloys of silver include platinum, osmium, palladium, and iridium. The metals may be used singly or in combination of two or more kinds thereof.

Regarding the metal nanowires, the shape thereof is not particularly limited as long as the metal nanowires are formed from the above-mentioned metals into a solid structure, and the shape can be appropriately selected according to the use. For example, the metal nanowires can adopt any arbitrary shape such as a cylindrical shape, a cuboid shape, or a pillar shape with a polygonal cross-section. The shape is preferably a cylindrical shape from the viewpoint that the thermoelectric conversion layer acquires higher transparency, and it is preferable that the metal nanowires have a cross-sectional shape of a polygon with rounded corners. The cross-sectional shape of the metal nanowires can be investigated by making an observation by transmission electron microscopy (TEM).

The average length in the major axis direction of the metal nanowires is preferably 1 μm or more, more preferably 1 μm to 40 μm, even more preferably 3 μm to 35 μm, and particularly preferably 5 μm to 30 μm, from the viewpoints similar to those of the carbon nanomaterial as described above. Meanwhile, in a case in which a metal nanowire is bent, a circle having the bent wire as an are is considered, and the value calculated from the radius and curvature of the circle is designated as the length in the major axis.

The average length in the minor axis direction (may be referred to as “average minor axis diameter” or “average diameter”) of the metal nanowires is likewise preferably 50 nm or less, more preferably 1 nm to 50 nm, even more preferably 10 nm to 40 nm, and particularly preferably 15 nm to 35 nm. Meanwhile, regarding the minor axis length in a case in which the minor axis of the metal nanowires is not circular, the longest length is designated as the minor axis length.

Metal nanowires can be produced by any production method: however it is preferable to produce metal nanowires by a production method of reducing metal ions while heating the metal in a solvent in which a halogen compound and a dispersible additive are dissolved, as described in JP2012-230881A, Details of the halogen compound, the dispersible additive, the solvent and the heating conditions are described in JP2012-230881A, Furthermore, in addition to this production method, metal nanowires can also be produced by, for example, the production methods respectively described in JP2009-215594A, JP2009-242880A, JP2009-299162A, JP2010-84173A, and JP2010-86714A.

Regarding metal nanotubes, the shape thereof is not particularly limited as long as metal nanotubes are formed from the above-mentioned metals in a hollow structure, and the nanotubes may be of a monolayer type or a multilayer type. From the viewpoint of having excellent electrically conductive properties and thermally conductive properties, it is preferable that the metal nanotubes are monolayer nanotubes.

The thickness (difference between the outer diameter and the inner diameter) of the metal nanotubes is preferably 3 nm to 80 nm, and more preferably 3 nm to 30 nm, from the viewpoints of durability, transparency, film forming properties, electrically conductive properties, and the like. It is desirable that the metal nanotubes have an average length in the major axis direction of at least 5 nm. The average length in the major axis direction of the metal nanotubes is preferably 1 μm to 40 μm, more preferably 3 μm to 35 μm, and even more preferably 5 μm to 30 μm, from the viewpoints similar to those of the carbon nanomaterial as described above. It is preferable that the average length in the minor axis direction of the metal nanotubes is the same as the average length in the minor axis of the metal nanowires.

Metal nanotubes may be produced by any production method, and production can be achieved by, for example, the production method described in US2005/0056118A.

Metal nanoparticles may be particulate or powdered fine metal particles formed from the metals described above, and may be simple fine metal particles, fine metal particles having their surfaces coated with a protective agent, or fine metal particles which have coated surfaces and are dispersed in a dispersing medium. Preferred examples of the metal used in the metal nanoparticles include, among the metals described above, silver, copper, gold, palladium, nickel, and rhodium. Furthermore, an alloy formed from at least two kinds of these metals, an alloy of iron and at least one kind of these metals, and the like can also be used. Examples of the alloy formed from two kinds of metal include a platinum-gold alloy, a platinum-palladium alloy, a gold-silver alloy, a silver-palladium alloy, a palladium-gold alloy, a rhodium-palladium alloy, a silver-rhodium alloy, a copper-palladium alloy, and a nickel-palladium alloy. Furthermore, examples of the alloy with iron include an iron-platinum alloy, an iron-platinum-copper alloy, an iron-platinum-tin alloy, an iron-platinum-bismuth alloy, and an iron-platinum-lead alloy. These metals or alloys can be used singly or in combination of two or more kinds thereof.

It is desirable that the metal nanoparticles have an average particle size as an average length in the major axis direction of at least 5 nm, and although there are no particular limitations, for example, the average particle size is preferably 150 nm or less from the viewpoint of having excellent electrically conductive properties.

Suitable examples of the protective agent for the fine metal particles include the protective agents described in JP2012-222055A, More suitable examples include protective agents each having a linear or branched alkyl chain having 10 to 20 carbon atoms, particularly fatty acids or aliphatic amines, and aliphatic thiols or aliphatic alcohols. Here, when the alkyl chain has 10 to 20 carbon atoms, the metal nanoparticles have high storage stability and excellent electrically conductive properties. Suitable examples of the fatty acids, aliphatic amines, aliphatic thiols, and aliphatic alcohols include those compounds described in JP2012-222055A.

Metal nanoparticles may be produced by any production method, and examples of the production method include a method for vapor deposition in gas, a sputtering method, a metal vapor synthesis method, a colloidal method, an alkoxide method, a co-precipitation method, a homogeneous precipitation method, a thermal decomposition method, a chemical reduction method, an amine reduction method, and a solvent evaporation method. These production methods respectively have unique features; however, particularly in a case in which production in large quantities is intended, it is preferable to use a chemical reduction method or an amine reduction method. On the occasion of carrying out these production methods, known reducing agents can be appropriately used as necessary, in addition to selecting and using the protective agent described above.

<Polymer Compound>

The polymer compound used for the invention has a repeating unit represented by the following Formula (1):

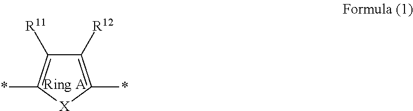

In Formula (1), ring A represents a conjugated hydrocarbon ring or a conjugated heterocyclic ring; X represents a group having one or two or more atoms selected from the group consisting of a carbon atom, an oxygen atom, a sulfur atom, a nitrogen atom, a phosphorus atom and a silicon atom, shared as ring-constituting atoms of the ring A; the average inter-unit distance of the ring A is 1.42 Å or less; R¹¹ and R¹² each independently represent a substituent, and may be bonded to each other to form a ring: and the symbol * represents a bonding position for the repeating unit.

In regard to the polymer compound of the invention, as shown below, the ring A (main chain) can adopt an endocyclic conjugated type resonant structure (canonical structure) and an exocyclic conjugated, pseudo-quinoid type canonical structure.

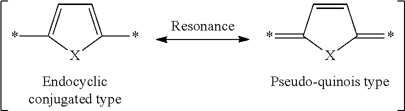

The standard interatomic distance is 1.54 Å in the case of a carbon-carbon single bond (C—C), and is 1.34 Å to 1.395 Å in the case of a carbon-carbon double bond (C═C), Therefore, in regard to the polymer compound of the invention, when the average inter-unit distance of the ring A is 1.42 Å or less, the pseudo-quinoid type canonical structure becomes more stable than the endocyclic conjugated type resonant structure, and the contribution thereof is increased.

Particularly, the repeating unit represented by Formula (2) shown below has a ring B, which is an aromatic ring, fused to the ring A, and thus it is speculated that the pseudo-quinoid type canonical structure becomes even more stabilized, and the contribution thereof is further increased.

The contribution ratio of these endocyclic conjugated type and pseudo-quinoid type resonant structures can be determined based on the average inter-unit distance L mentioned above. That is, as the average inter-unit distance L becomes shorter, the double bond character is enhanced, and therefore, it is considered that the pseudo-quinoid type resonant structure becomes more stabilized than the endocyclic conjugated type resonant structure. Due to this enhancement of the double bond character, free rotation of the bonds that form the main chain is suppressed, and the planarity of the main chain is increased. Furthermore, according to the invention, when the average inter-unit distance L of the ring A is 1.42 Å or less, the optical band gap tends to decrease.

On the contrary, as the average inter-unit distance L becomes longer, the single bond character (singlet bond character) is enhanced, and therefore, it is speculated that the endocyclic conjugated resonant structure becomes stabilized. When the average inter-unit distance L is longer than 1.42 Å, the contribution of the pseudo-quinoid structure is decreased, and the optical band gap tends to increase.

According to the invention, the average inter-unit distance L of the ring A is desirably 1.42 Å or less, preferably 1.41 Å or less, and more preferably 1.40 Å or less.

In regard to the pseudo-quinoid type canonical structure, since conjugation extends in the main chain direction, carriers can easily move around in the molecule through this conjugated chain. Also, since planarity of the main chain is increased, overlapping of the π-orbitals between molecules is increased, and carrier hopping between molecules is promoted. As such, carriers can easily move around both intramolecularly and intermolecularly, it is speculated that the carrier mobility increases, and as the contribution of this pseudo-quinoid type canonical structure increases, the carrier mobility increases even further. In addition, the polymer compound of the invention is easily adsorbed to the electroconductive nanomaterial, and carrier transport paths between the polymer compound and the electroconductive nanomaterial of the invention are densely formed. As a result, it is speculated that since thermally excited carriers generated in the polymer compound of the invention can easily move to the adsorbed electroconductive nanomaterial, diffusibility of the carriers is enhanced, and the electrical conductivity is also increased, the thermoelectric conversion performance is enhanced.

According to the invention, the optical band gap is preferably from 0.1 eV to 1.1 eV, more preferably from 0.1 eV to 1.0 eV, and even more preferably from 0.1 eV to 0.9 eV.

Here, the optical band gap is a forbidden band, and is the energy levels from the top of the valence band (highest energy band occupied by electrons in a band structure) to the bottom of the conduction band (lowest energy band that is empty of electrons), and the energy difference.

According to the invention, the optical band gap refers to a band gap that is determined by the absorption edge on the longer wavelength side in the absorption spectrum of the polymer compound of the invention, and specifically, the optical band gap can be determined by the following Formula (B):

Optical band gap (eV)=1240/absorption long-wavelength edge (nm) Formula (B)

In regard to Formula (B), the absorption long-wavelength edge refers to the wavelength (nm) of the absorption edge on the longer wavelength side in the absorption spectrum. The absorption spectrum can be measured using a spectrophotometer, Specifically, the polymer compound of the invention is dissolved in an organic solvent in which it is soluble, and the solution is applied on a quartz substrate to form a film. The absorption spectrum of this coating film is measured using a spectrophotometer. The wavelength λ5 (unit: nm) of the absorption edge on the longer wavelength side, at which the absorbance is 5% with respect to the maximum value of absorbance (λmax), is determined. λ5 thus determined is employed as the absorption long wavelength edge, and the optical band gap (unit: eV) is calculated by Formula (B). Regarding the spectrophotometer, an ultraviolet-visible-near infrared (UV-Vis-NIR) spectrophotometer or the like can be used.

For an enhancement of the thermoelectric conversion performance, it is effective to increase the probability of thermal excitation, and to increase the amount of generation of thermal excitons (amount of thermally excited carriers). However, since the amount of heat energy used for thermoelectric conversion is smaller than the amount of light energy, the amount of thermal excitons generated may not be sufficient.

Since the polymer compound of the invention has a large contribution from the pseudo-quinoid type canonical structure and has a low optical band gap, the polymer compound has an increased probability of thermal excitation and is easily thermally excited even with a smaller amount of heat. As a result, it is speculated that the amount of thermally excited carriers on a high temperature side of the thermoelectric conversion element increases, the thermoelectromotive force (Seebeck coefficient) increases, and the thermoelectric conversion performance is enhanced.

Furthermore, when the polymer compound of the invention is used together with an electroconductive nanomaterial, the polymer compound of the invention functions as a dispersing binder for the electroconductive nanomaterial, and dispersibility of the electroconductive nanomaterial is enhanced.

It is speculated that the polymer compound of the invention has a large contribution from the pseudo-quinoid type canonical structure having high planarity, and thereby, the polymer compound can easily be adsorbed to the electroconductive nanomaterial as a result of an intermolecular interaction such as a π-π interaction.

As such, it is speculated that when the polymer compound of the invention is used in combination with the electroconductive nanomaterial, the thermoelectromotive force and electrical conductivity are increased, and consequently, the thermoelectric conversion performance is further enhanced.

The content ratio of the polymer compound of the invention in the total solid content of the thermoelectric conversion material is preferably 50 parts by mass to 2,000 parts by mass, and more preferably 80 parts by mass to 600 parts by mass, relative to 100 parts by mass of the electroconductive nanomaterial, in view of the thermoelectric conversion performance.

In the thermoelectric conversion material of the invention, polymer compounds of the invention may be used singly, or two or more kinds thereof may be used in combination.

The polymer compound of the invention has a repeating unit represented by Formula (1) described above, and the main chain formed by including this repeating unit is a conjugated polymer in which the repeating units are conjugated via π-electrons or lone pair electrons.

In the following, the repeating unit represented by Formula (1) will be explained in detail.

The ring A of this repeating unit is preferably a conjugated heterocyclic ring, from the viewpoint of the interaction (adsorbability) with the electroconductive nanomaterial and from the viewpoint of the electrically conductive properties of the polymer.

X is preferably a group containing one atom selected from the group consisting of a carbon atom, a sulfur atom, a nitrogen atom, a phosphorus atom and a silicon atom as a ring-constituting atom, and more preferably a group containing one atom selected from the group consisting of a carbon atom, a sulfur atom and a nitrogen atom as a ring-constituting atom.

In regard to X, these atoms each have a hydrogen atom or a substituent depending on the valence of the atom. There are no particular limitations on the atoms that constitute this substituent, and examples thereof include a carbon atom, an oxygen atom, a sulfur atom, a nitrogen atom, a phosphorus atom, a hydrogen atom, a boron atom, a silicon atom, and a selenium atom. That is, X has a ring-constituting atom and a substituent or a hydrogen atom bonded thereto.

Examples of X include groups such as —Y(═O)ₘ—, —Y(═S)—, —YR^{x}ₘ—, —Y(═CR^{x}₂)—, —Y(—OH)ₘ—, —Y(—OR)ₘ—, and —Y(—SR)ₘ—; groups combining two or more of these groups: and groups combining these groups with —O—. Among them, preferred examples include —Y(═O)ₘ—, —YR^{x}ₘ—, —Y(═CR^{x}₂)—, and groups combining two or more of these groups: and more preferred examples include —Y(═O)ₘ—, —YR^{x}ₘ—, —Y(═CR^{x}₂)—, —Y(═O)ₘ—Y(═O)ₘ—, and —YR^{x}ₘ—YR^{x}ₘ—. Here, Y has the same meaning as the ring-constituting atom of X, while a preferred range thereof is also the same, and R^{x} represents a hydrogen atom or a substituent. m represents an integer of 1 or more and is selected according to the valence of Y, and m is preferably 1 or 2.

Specific examples of X include groups such as —C(═O)—, —C(═S)—, —CR^{x}₂—, —C(═CR^{x}₂)—, —S(═O)—, —S(═O)₂—, —N(→O)— (also indicated as —N(═O)—), —P(═O)R—, —PR—, —P(OR)₃—, —SiR₂—, —Si(OR)₂—, and —SiR₂—SiR₂—; groups combining two or more of these groups; and groups combining these groups with —O—. Among them, preferred examples of X include —C(═O), —CR^{x}₂—, —C(═CR^{x}₂)—, —C(═O)—C(═O)—, —CR^{x}₂—CR^{x}₂—, —S(═O)—, —S(═O)₂—, and —N(→O)—.

The substituent carried by X and the substituent R^{x} are not particularly limited, and examples thereof include a substituent W that will be described below. Among them, an alkyl group or an aryl group is preferred.

The alkyl group may be linear, branched or cyclic, and a linear alkyl group is preferred. The carbon number of the alkyl group is preferably 1 to 20, and more preferably 1 to 10, and examples thereof include those groups mentioned as examples of the substituent W.

The aryl group is preferably an aryl group having 6 to 12 carbon atoms, and examples thereof include phenyl.

The ring A having such a group is not particularly limited; however, a 5-membered to 7-membered ring is preferred, and a 5-membered ring or a 6-membered ring is more preferred.

The ring structure of the ring A (excluding the substituents R¹¹ and R¹²) is preferably represented by the following Formulae (3) to (8). In the respective formulae, the symbol * represents a bonding position directed to the ring A as a repeating unit.

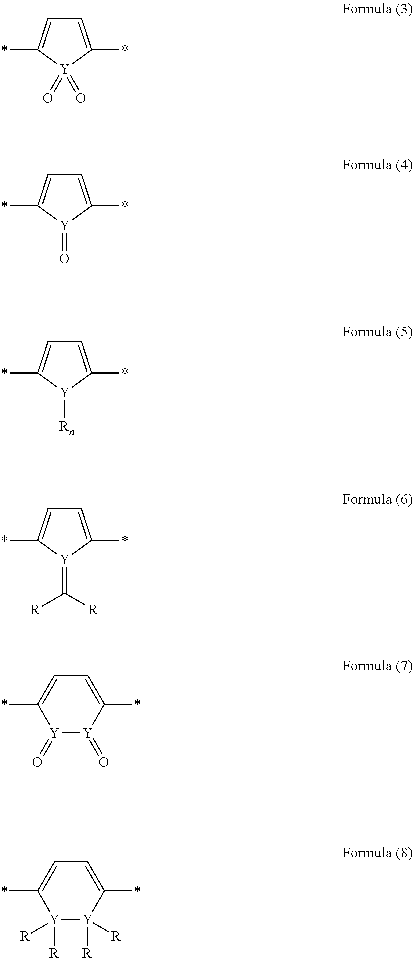

In Formula (3) to Formula (8), each Y independently represents an atom selected from the group consisting of a carbon atom, a sulfur atom, a nitrogen atom, a phosphorus atom, and a silicon atom. Two Y's in Formulae (7) and (8) may be identical or different. Meanwhile, Y is selected so as to satisfy the valence of Y in each formula. For example, a carbon atom is not selected for Formula (3).

In Formula (3) to Formula (8), regarding Y, the atom is selected from the group mentioned above, so as to correspond to the preferred X's specifically exemplified above. Preferably, Y represents a sulfur atom in Formula (3), Y represents a carbon atom, a sulfur atom or a nitrogen atom in Formula (4), and Y represents a carbon atom, a phosphorus atom or a silicon atom in Formula (5). For each of Formula (6) to Formula (8), Y represents a carbon atom.

R represents an alkyl group or an aryl group, and has the same meaning as the alkyl group or aryl group for the substituent R^{x}, while a preferred range thereof is also the same. In a case in which n represents an integer of 2 or more in Formula (5), and in the cases of Formula (6) and Formula (8), plural R's may be identical or different.

n represents an integer of 1 or more and is selected according to the valence of Y When Y is a carbon atom, n is 2.

In Formula (l), R¹¹ and R¹² each independently represent a substituent. This substituent is not particularly limited, and may be a substituent W that will be described below. However, from the viewpoints of the thermoelectric conversion characteristics and dispersibility, it is preferable that R¹¹ and R¹² are linked to each other to form a ring, and it is more preferable that they form an aromatic ring. In this case, it is preferable that the repeating structure represented by Formula (1) is represented by the following Formula (2).

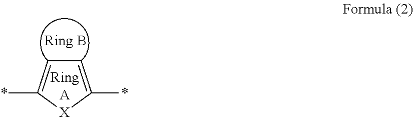

In Formula (2), the rings A and X have the same meanings as the rings A and X of Formula (1), and preferred examples thereof are also the same. The average inter-unit distance of the ring A is also the same as that of the ring A of Formula (1), and a preferred range thereof is also the same. The symbol * represents a bonding position for the repeating unit.

In Formula (2), ring B represents an aromatic ring. Ring B may be an aromatic hydrocarbon ring or an aromatic heterocyclic ring, and ring B is preferably a benzene ring or a 5-membered or 6-membered aromatic heterocyclic ring.

The aromatic hydrocarbon ring may be a monocyclic hydrocarbon ring having aromaticity, and its basal ring may be a benzene ring.

The aromatic heterocyclic ring is not particularly limited as long as it is a monocyclic heterocyclic ring having aromaticity; however suitable examples thereof include a 5-membered aromatic heterocyclic ring and a 6-membered aromatic heterocyclic ring. Examples of the heteroatom that constitutes the heterocyclic ring include a sulfur atom, a nitrogen atom, an oxygen atom, a silicon atom, and a selenium atom, and preferred examples thereof include an oxygen atom, a sulfur atom, and a nitrogen atom, while more preferred examples include a sulfur atom and a nitrogen atom. Examples of the 5-membered aromatic heterocyclic ring include a thiophene ring, a furan ring, a pyrrole ring, a selenophene ring, an imidazole ring, a pyrazole ring, an oxazole ring, an isoxazole ring, a thiazole ring, an isothiazole ring, a triazole ring, a thiadiazole ring, a diazole ring, a pyridine ring, and a pyrazine ring. Examples of the 6-membered aromatic heterocyclic ring include a pyridine ring, a pyrimidine ring, a pyridazine ring, a pyrazine ring, and a triazine ring. Among them, from the viewpoints of the thermoelectric conversion performance and dispersibility, a thiophene ring, a pyrrole ring, an imidazole ring, a pyrazole ring, a thiadiazole ring, a diazole ring, a pyridine ring, and a pyrazine ring are even more preferred.

The ring B is preferably a benzene ring or a 5-membered or 6-membered aromatic heterocyclic ring.

Ring B may be fused, and may have a substituent.

The ring fused to the ring B may be an aliphatic ring or an aromatic ring, and may also be a hydrocarbon ring or a heterocyclic ring. Among them, a ring containing an aromatic ring structure is preferred, and a ring containing an aromatic heterocyclic ring structure is more preferred. Examples of the aromatic hydrocarbon ring or aromatic heterocyclic ring that constitute the ring fused to the ring B include the aromatic hydrocarbon rings and aromatic heterocyclic rings mentioned above, and preferred examples thereof are also the same. The number of rings that may be fused to the ring B is not particularly limited; however, the number of rings is preferably 1 or 2.

The substituent for the ring B is not particularly limited, and may be a substituent W that will be described below. Above all, preferred examples include an alkyl group (particularly, one having 1 to 30 carbon atoms), an alkenyl group (particularly, one having 1 to 26 carbon atoms), an alkoxy group (particularly, one having 1 to 26 carbon atoms), an alkylthio group (particularly, one having 1 to 26 carbon atoms), an alkoxycarbonyl group (particularly, one having 1 to 26 carbon atoms), an aromatic hydrocarbon ring group, and an aromatic heterocyclic group.

The polymer compound may have at least one repeating unit represented by Formula (1) or Formula (2) as a repeating unit, and the polymer compound may have plural repeating units.

Furthermore, the polymer compound may also be a copolymer having the repeating unit represented by Formula (1) or Formula (2), and another repeating unit which is a repeating unit other than the repeating unit represented by Formula (1) or Formula (2) and can form a conjugated system of the main chain. The polymer compound may have one kind or plural kinds of such a repeating unit.

In addition, when the polymer compound has plural repeating units, the copolymerization method is not particularly limited, and may be any of block copolymerization, alternating copolymerization, random copolymerization, or graft copolymerization.

The other repeating unit described above may be any linking group or atoms capable of forming a conjugated system of the main chain, or a combination of such a linking group and such atoms. Such other repeating units are not particularly limited; however, at least one repeating unit selected from the group consisting of an ethenylene group, an ethynylene group, an arylene group, and a heteroarylene group is preferred.

The carbon number of the arylene group is preferably 6 to 20, and more preferably 6 to 15. The arylene group is preferably phenylene or naphthylene.

The arylene group contains atoms capable of forming a conjugated system of the main chain, preferably plural aromatic rings bonded to a nitrogen atom, and includes a group which is bonded to the main chain via different aromatic rings. An example of such a group is a divalent group obtainable from triphenylamine, which is bonded to the main chain via different phenyl groups.

Furthermore, the carbon number of the heteroarylene group is preferably 3 to 20, and more preferably 5 to 12. The heterocyclic ring that constitutes the heteroarylene group is not particularly limited; however, a 5-membered ring or a 6-membered ring is preferred. The heteroatom that constitutes the heterocyclic ring is not particularly limited; however, suitable examples thereof include a sulfur atom, a nitrogen atom, an oxygen atom, a silicon atom, and a selenium atom. Preferred examples of the heteroarylene group include a divalent thiophene ring, a divalent furan ring, a divalent pyrrole ring, a divalent selenophene ring, a divalent thiazole ring, a divalent oxazole ring, a divalent phosphole ring, a divalent phosphorine ring, a divalent thiadiazole ring, a divalent oxadiazole ring, a divalent pyrazole ring, a divalent imidazole ring, a divalent pyridine ring, a divalent pyrazine ring, a divalent pyridazine ring, a divalent triazine ring, a divalent triazole ring, and a divalent tetrazine ring.

The arylene group and the heteroarylene group may be respectively fused, and the ring that is fused to these groups has the same meaning as the above-described ring that is fused to the ring B, while preferred examples thereof are also the same. Examples of products that form a fused arylene group or a fused heteroarylene group include fluorene, dithienosilole, cyclopentadithiophene, benzodithiophene, thieno[3,4-b]thiophene, [1]benzothieno[3,2-b][1]benzothiophene, and benzofluorene. Meanwhile, in a case in which the arylene group and the heteroarylene group are fused, the linking position that links to the main chain may be a ring-constituting atom that constitutes a same ring, or may be a ring-constituting atom that constitutes different rings.

The other repeating unit may have a substituent. The substituent that may be carried by the other repeating unit has the same meaning as the substituent that may be carried by the ring B, and preferred examples thereof are also the same.

Examples of the substituent W include the groups described below.

An alkyl group (for example, methyl, ethyl, propyl, isopropyl, tert-butyl, pentyl, hexyl, octyl, dodecyl, tridecyl, tetradecyl, or pentadecyl), a cycloalkyl group (for example, cyclopentyl or cyclohexyl), an alkenyl group (for example, vinyl or allyl), an alkynyl group (for example, ethynyl or propargyl), an aromatic hydrocarbon ring group (also referred to as an aromatic carbon ring, aryl or the like; for example, phenyl, p-chlorophenyl, mesityl, tolyl, xylyl, naphthyl, anthryl, azulenyl, acenaphthenyl, fluorenyl, phenanthryl, indenyl, pyrenyl, and biphenylyl), an aromatic heterocyclic group (a 5-membered or 6-membered aromatic heterocyclic group is preferred, and the ring-constituting heteroatom is preferably a sulfur atom, a nitrogen atom, an oxygen atom, a silicon atom, boron, or a selenium atom; for example, pyridyl, pyrimidinyl, furyl, pyrrolyl, imidazolyl, benzimidazolyl, pyrazolyl, pyrazinyl, triazolyl (for example, 1,2,4-triazol-1-yl or 1,2,3-triazol-1-yl) oxazolyl, benzoxazolyl, thiazolyl, isoxazolyl, isothiazolyl, furazanyl, thienyl, quinolyl, benzofuryl, dibenzofuryl, benzothienyl, dibenzothienyl, indolyl, carbazolyl, carbolinyl, diazacarbazolyl (represents a compound in which one of the carbon atoms that constitute the carboline ring of the carbolinyl group has been substituted by a nitrogen atom), quinoxalinyl, pyridazinyl, triazinyl, quinazolinyl, phthalazinyl, borole, or azaborine), a heterocyclic group (a non-aromatic heterocyclic group, which may be a saturated ring or an unsaturated ring, and a 5-membered or 6-membered ring is preferred; the ring-constituting heteroatom is preferably a sulfur atom, a nitrogen atom, an oxygen atom, a silicon atom, or a selenium atom; for example, pyrrolidyl, imidazolidyl, morpholyl, or oxazolidyl), an alkoxy group (for example, methoxy, ethoxy, propyloxy, pentyloxy, hexyloxy, octyloxy, or dodecyloxy), a cycloalkoxy group (for example, cyclopentyloxy or cyclohexyloxy), an aryloxy group (for example, phenoxy or naphthyloxy), an alkylthio group (for example, methylthio, ethylthio, propylthio, pentylthio, hexylthio, octylthio, or dodecylthio), a cycloalkylthio group (for example, cyclopentylthio or cyclohexylthio), an arylthio group (for example, phenylthio or naphthylthio), an alkoxycarbonyl group (for example, methyloxycarbonyl, ethyloxycarbonyl, butyloxycarbonyl, octyloxycarbonyl, or dodecyloxycarbonyl), an aryloxycarbonyl group (for example, phenyloxycarbonyl or naphthyl oxycarbonyl), a sulfamoyl group (for example, aminosulfonyl, methylaminosulfonyl, dimethylaminosulfonyl, butylaminosulfonyl, hexylaminosulfonyl, cyclohexylaminosulfonyl, octylaminosulfonyl, dodecylaminosulfonyl, phenylaminosulfonyl, naphthylaminosulfonyl, or 2-pyridylaminosulfonyl),

an acyl group (for example, acetyl, ethylcarbonyl, propylcarbonyl, pentylcarbonyl, cyclohexylcarbonyl, octylcarbonyl, 2-ethylhexylcarbonyl, dodecylcarbonyl, acryloyl, methacryloyl, phenylcarbonyl, naphthylcarbonyl, or pyridylcarbonyl), an acyloxy group (for example, acetyloxy, ethylcarbonyloxy, butylcarbonyloxy, octylcarbonyloxy, dodecylcarbonyloxy, or phenylcarbonyloxy), an amide group (for example, methylcarbonylamino, ethylcarbonylamino, dimethylcarbonylamino, propyl carbonylamino, pentylcarbonylamino, cyclohexylcarbonylamino, 2-ethylhexylcarbonylamino, octylcarbonylamino, dodecylcarbonylamino, phenylcarbonylamino, or naphthylcarbonylamino), a carbamoyl group (for example, aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, or 2-pyridylaminocarbonyl), a ureido group (for example, methyureido, ethylureido, pentylureido, cyclohexylureido, octylureido, dodecylureido, phenylureido, naphthylureido, or 2-pyridylaminoureido), a sulfinyl group (for example, methylsulfinyl, ethylsulfinyl, butylsulfinyl, cyclohexylsulfinyl, 2-ethylhexylsulfinyl, dodecylsulfinyl, phenylsulfinyl, naphthylsulfinyl, or 2-pyridylsulfinyl), an alkylsulfonyl group (for example, methylsulfonyl, ethylsulfonyl, butylsulfonyl, cyclohexylsulfonyl, 2-ethylhexylsulfonyl, or dodecylsulfonyl), an arylsulfonyl group or a heteroarylsulfonyl group (for example, phenylsulfonyl, naphthylsulfonyl, or 2-pyridylsulfonyl), an amino group (including an amino group, an alkylamino group, an alkenylamino group, an arylamino group, and a heterocyclic amino group; for example, amino, ethylamino, dimethylamino, butylamino, cyclopentylamino, 2-ethylhexylamino, dodecylamino, anilino, naphthylamino, or 2-pyridylamino), a cyano group, a nitro group, a hydroxyl group, a mercapto group, and a silyl group (for example, trimethylsilyl, triisopropylsilyl, triphenylsilyl, or phenyldiethylsilyl).

Each of these groups may further have a substituent, and examples of this substituent include the substituents described above. Examples thereof include an aralkyl group which is an alkyl group substituted with an aryl group, and a hydroxyalkyl group which is an n alkyl group substituted with a hydroxyl group.

Specific examples of the polymer compound are shown below; however, the invention is not intended to be limited to these. The polymer compounds shown below are formed from the repeating units shown below. The average inter-unit distance L, which is obtained by the calculation method described above, of the compounds that are not used in Examples are shown below the repeating units. Meanwhile, the abbreviation “Ph” represents a phenyl group.

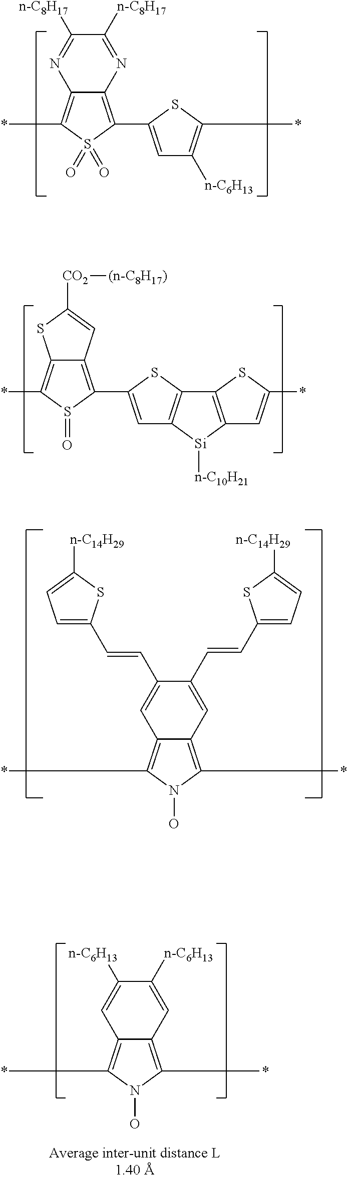

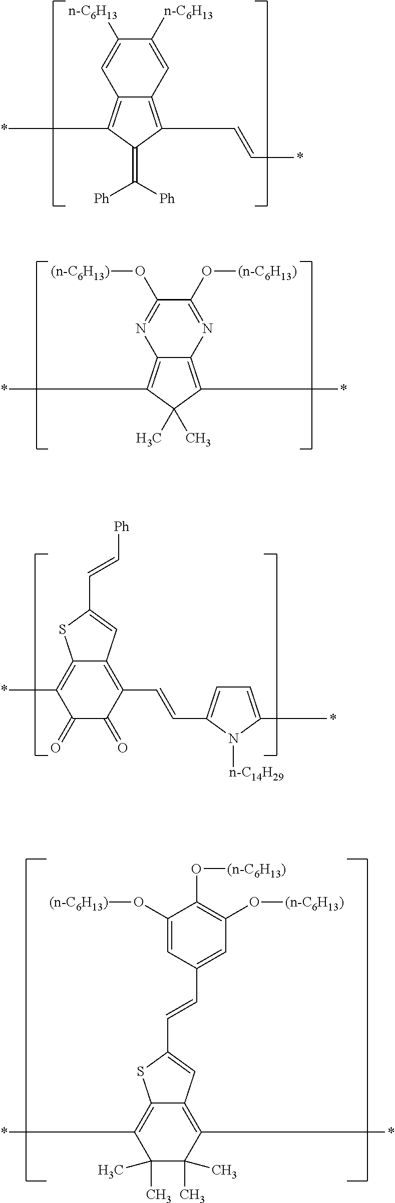

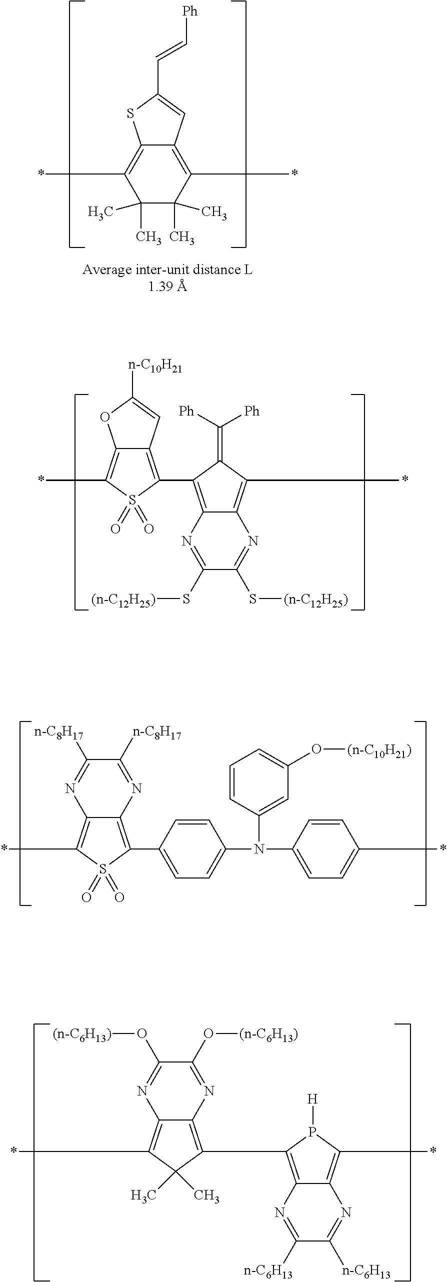

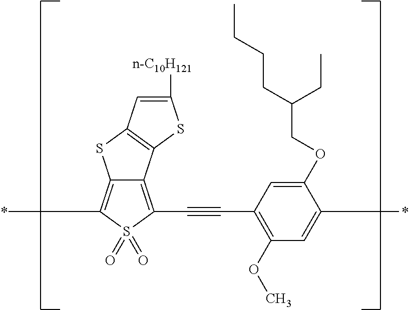

The polymer compound has a weight average molecular weight of preferably 5,000 to 300,000, and more preferably 10,000 to 200,000.

The weight average molecular weight can be measured by gel permeation chromatography (GPC). For example, gel permeation chromatography is performed under the configuration and conditions of apparatus: “ALLIANCE GPC2000 (manufactured by Waters Corporation)”, columns: TSKgel GMH₆-HT×2+TSKgel GMH₆-HTL×2 (all 7.5 mm I.D.×30 cm, manufactured by Tosoh Corporation), column temperatures: 140° C., detector: differential refractometer, and mobile phase: solvent (for example, o-dichlorobenzene), and regarding the configuration of the molecular weight, the average molecular weight can be determined using polystyrene standards.

The polymer compound can be synthesized by a method equivalent to the method described in Chem. Rev., 1997, 97, 173-205, or the like.

<Polymer Binder>

It is preferable that the thermoelectric conversion material of the invention contains a polymer binder, in addition to the electroconductive nanomaterial and the polymer compound described above. By incorporating a polymer binder, the thermoelectric conversion performance of the thermoelectric conversion element can be further enhanced.

Examples of the polymer binder include a conjugated polymer binder and a non-conjugated polymer binder. It is preferable that the thermoelectric conversion material of the invention contains at least one of a conjugated polymer binder and a non-conjugated polymer binder, and it is more preferable that the thermoelectric conversion material contains both a conjugated polymer binder and a non-conjugated polymer binder. When the thermoelectric conversion material contains both a conjugated polymer binder and a non-conjugated polymer binder, a further enhancement of the thermoelectric conversion performance can be realized. Furthermore, the thermoelectric conversion material may contain two or more kinds of conjugated polymer binder or non-conjugated polymer binder.

The polymer binder may be a homopolymer, or may be a copolymer. In the case of a copolymer, the polymer binder may be a block copolymer, a random copolymer, or an alternating copolymer, and may also be a graft copolymer or the like.

The content ratio of the polymer binder in the thermoelectric conversion material is not particularly limited. In view of the thermoelectric conversion performance, the percent content of the polymer binder is preferably 10% by mass to 80% by mass, more preferably 20% by mass to 70% by mass, and even more preferably 30% by mass to 60% by mass, relative to the total solid content of the thermoelectric conversion material, that is, in the thermoelectric conversion layer.

The content ratio of the conjugated polymer binder in the thermoelectric conversion material is not particularly limited. In view of the thermoelectric conversion performance, the content ratio is within a range that satisfies the content ratio of the polymer binder described above, and the content ratio is preferably 15% by mass to 70% by mass, more preferably 25% by mass to 60% by mass, and even more preferably 30% by mass to 50% by mass, relative to the total solid content of the thermoelectric conversion material.

Similarly, the content ratio of the non-conjugated polymer binder in the thermoelectric conversion material is not particularly limited. In view of the thermoelectric conversion performance, the content ratio is within the range that satisfies the content ratio of the polymer binder described above, and the content ratio of the non-conjugated polymer binder is preferably 20% by mass to 70% by mass, more preferably 30% by mass to 65% by mass, and even more preferably 35% by mass to 60% by mass, relative to the total solid content of the thermoelectric conversion material.

1. Conjugated Polymer Binder

A conjugated polymer binder is a compound having a structure in which the main chain is conjugated via π-electrons or lone pair electrons, and there are no particular limitations as long as the conjugated polymer binder is a conjugated polymer other than the polymer compound described above. Regarding such a conjugated structure, for example, a structure in which single bonds and double bonds are alternately arranged with regard to the carbon-carbon bonds on the main chain, may be mentioned.

The “conjugated polymer binder” as used herein is a compound used in combination with the polymer compound, and is a compound different from the polymer compound described above.

For example, in a case in which the conjugated polymer binder has a ring that forms the main chain, the average inter-unit distance of this ring is more than 1.42 Å. Specifically, the average inter-unit distance L of poly(3-hexylthiophene), which is a general n-conjugated polymer, is 1.45 Å.

Such a conjugated polymer binder may be a conjugated polymer containing, as a repeating structure, a constituent component derived from at least one compound selected from the group consisting of a thiophene compound, a pyrrole compound, an aniline compound, an acetylene compound, a p-arylene compound, a p-arylene-vinylene compound, a p-arylene-ethynylene compound, a p-fluorenylene-vinylene compound, a fluorene compound, an aromatic polyamine compound (also referred to as an arylamine compound), a polyacene compound, a polyphenanthrene compound, a metal phthalocyanine compound, a p-xylene compound, a vinylene sulfide compound, a m-phenylene compound, a naphthalene-vinylene compound, a p-phenylene oxide compound, a phenylene sulfide compound, a furan compound, a selenophene compound, an azo compound, and a metal complex compound.

Among them, from the viewpoint of the thermoelectric conversion performance, the conjugated polymer binder is preferably a conjugated polymer containing, as a repeating structure, a constituent component derived from at least one compound selected from the group consisting of a thiophene compound, a pyrrole compound, an aniline compound, an acetylene compound, a p-phenylene compound, a p-phenylene-vinylene compound, a p-phenylene ethynylene compound, a fluorene compound, and an arylamine compound.

There are no particular limitations on the substituent which each of the compounds described above can have; however, in consideration of the compatibility with other components, the kind of the dispersing medium that can be used, and the like, it is preferable to appropriately select and introduce a substituent that can increase the dispersibility of the conjugated polymer binder in the dispersing medium.

As examples of the substituent, in a case in which an organic solvent is used as a dispersing medium, a linear, branched or cyclic alkyl group, an alkenyl group, an alkynyl group, an alkoxy group, a thioalkyl group, an alkoxyalkyleneoxy group, an alkoxyalkyleneoxyalkyl group, a crown ether group, an aryl group, and the like can be preferably used. These groups may further have a substituent. Furthermore, the number of carbon atoms of the substituent is, without any particular limitations, preferably 1 to 12, and more preferably 4 to 12. Particularly, a long-chain alkyl group having 6 to 12 carbon atoms, an alkoxy group, a thioalkyl group, an alkoxyalkyleneoxy group, and an alkoxyalkyleneoxyalkyl group are preferred.

On the other hand, in a case in which a water-based medium is used as a dispersing medium, it is preferable to further introduce a hydrophilic group such as a carboxylic acid group, a sulfonic acid group, a hydroxyl group, or a phosphoric acid group at an end of each monomer or to the substituent. In addition to that, a dialkylamino group, a monoalkylamino group, an amino group, a carboxyl group, an ester group, an amide group, a carbamate group, a nitro group, a cyano group, an isocyanate group, an isocyano group, a halogen atom, a perfluoroalkyl group, a perfluoroalkoxy group or the like can be introduced as a substituent, which is preferable.

The number of substituents that can be introduced is also not particularly limited, and in consideration of dispersibility, compatibility, electrically conductive properties, and the like of the conjugated polymer binder, one or plural substituents can be appropriately introduced.

Regarding the conjugated polymer binder, the “electroconductive polymer” described in paragraphs “0014” to “0047” of JP2012-251132A can be suitably used, the disclosure of which is preferably incorporated herein.

The molecular weight of the conjugated polymer binder is preferably 3,000 to 200,000, and more preferably 5,000 to 100,000, as the weight average molecular weight. The weight average molecular weight can be measured by gel permeation chromatography (GPC). A specific measurement method therefor is as described above.

2. Non-Conjugated Polymer Binder

A non-conjugated polymer binder is a polymer compound which does not exhibit electrically conductive properties in the conjugated structure of the polymer main chain. Preferably, a non-conjugated polymer binder is a polymer other than a polymer in which the polymer main chain is composed of rings, groups or atoms selected from aromatic rings (a carbon ring-based aromatic ring and a heteroaromatic ring), an ethynylene bond, an ethenylene bond, and heteroatoms having lone pair electrons, or a polymer which contain these groups but have the groups incorporated in an isolated manner.

Such a non-conjugated polymer binder is not particularly limited, and any non-conjugated polymer binder that is conventionally known can be used. From the viewpoint of the thermoelectric conversion performance, a non-conjugated polymer containing, as a repeating structure, a constituent component derived from at least one compound selected from the group consisting of a vinyl compound, a (meth)acrylate compound, a carbonate compound, an ester compound, an amide compound, an imide compound, a fluorine compound, and a siloxane compound, is preferred. These compounds may each have a substituent, and examples of the substituent include the same ones as the substituents for the conjugated polymer binder.

According to the invention, the term “(meth)acrylate” represents both or any one of acrylate and methacrylate, and also includes a mixture thereof.

Specific examples of a vinyl compound include vinylarylamines such as styrene, vinylpyrrolidone, vinylcarbazole, vinylpyridine, vinylnaphthalene, vinylphenol, vinyl acetate, styrenesulfonic acid, and vinyltriphenylamine; and vinyltrialkylamines such as vinyltributylamine. Furthermore, in addition to these, other examples include olefins having 2 to 4 carbon atoms (ethylene, propylene, and butene) corresponding to the constituent components of the polyolefin.

Specific examples of a (meth)acrylate compound include acrylate monomers including unsubstituted alkyl group-containing hydrophobic acrylates such as methyl acrylate, ethyl acrylate, propyl acrylate, and butyl acrylate; and hydroxyl group-containing acrylates such as 2-hydroxyethyl acrylate, 1-hydroxyethyl acrylate, 2-hydroxypropyl acrylate, 3-hydroxypropyl acrylate, 1-hydroxypropyl acrylate, 4-hydroxybutyl acrylate, 3-hydroxybutyl acrylate, 2-hydroxybutyl acrylate, and 1-hydroxybutyl acrylate; and methacrylate monomers obtained by replacing the acryloyl groups of these monomers with methacryloyl groups.

Specific examples of a polycarbonate containing a constituent component derived from a carbonate compound as a repeating structure, include a general-purpose polycarbonate composed of bisphenol A and phosgene, IUPIZETA (trade name, manufactured by Mitsubishi Gas Chemical Company, Inc.), and PANLITE (trade name, manufactured by Teijin Chemicals, Ltd.)

Examples of compounds that can constitute an ester compound include polyalcohols, polycarboxylic acids, and hydroxy acids such as lactic acid. Specific examples of a polyester include VYLON (trade name, manufactured by Toyobo Co., Ltd.).

Specific examples of a polyamide containing a constituent component derived from an amide compound as a repeating structure include PA-100 (trade name, manufactured by T&K Toka Corporation).

Specific examples of a polyimide containing a constituent component corresponding to an imide compound as a repeating structure include SOLPIT 6,6-PI (trade name, manufactured by Solpit Industries, Ltd.).

Specific examples of a fluorine compound include vinylidene fluoride and vinyl fluoride.

Specific examples of a polysiloxane containing a constituent component derived from a siloxane compound as a repeating structure include polydiphenylsiloxane and polyphenylmethylsiloxane.

The molecular weight of the non-conjugated polymer binder is preferably 5,000 to 300,000, and more preferably 10,000 to 150,000, as the weight average molecular weight. The weight average molecular weight can be measured by gel permeation chromatography (GPC). A specific measurement method therefor is as described above.

<Dispersing Medium>

It is preferable that the thermoelectric conversion material of the invention contains a dispersing medium, and it is more preferable that the electroconductive nanomaterial is dispersed in this dispersing medium.

Any dispersing medium can be used as long as an electroconductive nanomaterial can be dispersed therein, and water, an organic solvent, and mixed solvents thereof can be used. The dispersing medium is preferably an organic solvent, and preferred examples include alcohols; aliphatic halogen solvents such as chloroform; aprotic polar solvents such as N,N-dimethylformamide (DMF), N-methylpyrrolidone (NMP), and dimethyl sulfoxide (DMSO); aromatic solvents such as chlorobenzene, dichlorobenzene, benzene, toluene, xylene, mesitylene, tetralin, tetramethylbenzene, and pyridine; ketone solvents such as cyclohexanone, acetone, and methyl ethyl ketone; and ether solvents such as diethyl ether, tetrahydrofuran (THF), t-butyl methyl ether, dimethoxyethane, and diglyme, while more preferred examples include halogen solvents such as chloroform, aprotic polar solvents such as DMF and NMP; aromatic solvents such as dichlorobenzene, xylene, tetralin, and tetramethylbenzene; and ether solvents such as THF.

For the thermoelectric conversion material of the invention, the dispersing media can be used singly or in combination of two or more kinds thereof.

Furthermore, it is preferable that the dispersing medium is degassed in advance. It is preferable that the dissolved oxygen concentration in the dispersing medium is adjusted to 10 ppm or less. Examples of the method for degassing include a method of applying ultrasonic waves under reduced pressure, and a method of bubbling an inert gas such as argon.

Furthermore, it is preferable that the dispersing medium is dehydrated in advance. The amount of moisture in the dispersing medium is preferably adjusted to 1000 ppm or less, and more preferably to 100 ppm or less. Regarding the dehydration method of the dispersing medium, known methods such as a method of using a molecular sieve, and distillation can be used.

The amount of the dispersing medium in the thermoelectric conversion material is preferably 25% by mass to 99.99% by mass, more preferably 30% by mass to 99.95% by mass, and even more preferably 30% by mass to 99.9% by mass, relative to the total amount of the thermoelectric conversion material.

<Dopant>

From the viewpoint that the electrically conductive properties of the thermoelectric conversion layer can be further enhanced by an increase in the carrier concentration, it is preferable that the thermoelectric conversion material of the invention contains a dopant, and in a case in which the thermoelectric conversion material contains the conjugated polymer binder, it is more preferable that the thermoelectric conversion material contains a dopant.

A dopant is a compound that is doped into the conjugated polymer binder described above, and the dopant may be any compound which can dope this conjugated polymer binder with positive charges (p-type doping) by protonizing the conjugated polymer binder or removing electrons from the n-conjugated system of the conjugated polymer binder. Specifically, an onium salt compound described below, an oxidizing agent, an acidic compound, an electron acceptor compound, and the like can be used.

1. Onium Compound

The onium salt compound used as a dopant is preferably a compound which generates an acid when irradiated with active energy radiation (radiation, electromagnetic waves, or the like), or when energy such as heat is applied (acid generator or acid precursor). Examples of such an onium salt compound include a sulfonium salt, an iodonium salt, an ammonium salt, a carbonium salt, and a phosphonium salt. Among them, preferred examples include a sulfonium salt, an iodonium salt, an ammonium salt, and a carbonium salt; more preferred examples include a sulfonium salt, an iodonium salt, and a carbonium salt; and particularly preferred examples include a sulfonium salt and an iodonium salt. The anionic moiety that constitutes the relevant salts may be a counterion of a strong acid.

Regarding the onium salt compound described above, specifically, the onium salt compounds described in JP2012-251132A can be suitably used, the disclosure of which is preferably incorporated herein.

2. Oxidizing Agent, Acidic Compound, Electron Acceptor Compound

Examples of the oxidizing agent that is used as a dopant for the invention include halogens (Cl₂, Br₂, I₂, IC, ICl, ICl₃, IBr, and IF), Lewis acids (PF₅, AsF₅, SbF₅, BF, BCl₃, BBr₃, and SO₃), transition metal compounds (FeCl₃, FeOCl, TiCl₄, ZrCl₄, HfCl₄, NbF₅, NbCl₅, TaCl₅, MoF₅, MoCl₅, WF₆, WCl₆, UF₆, LnCl₃ (Ln=lanthanoids such as La, Ce, Pr, Nd, and Sm), as well as O₂, O₃, XeOF₄, (NO₂⁺)(SbF₆⁻), (NO₂⁺)(SbCl₆⁺), (NO₂⁺)(BF₄⁻), FSO₂OOSO₂F, AgClO₄, H₂IrCl₆, and La(NO₃)₃.6H₂O.

Examples of the acidic compound include polyphosphoric acids (biphosphoric acid, pyrophosphoric acid, triphosphoric acid, tetraphosphoric acid, metaphosphoric acid, and the like), hydroxy compounds, carboxy compounds, sulfonic acid compounds, and protic acids (HF, HCl, HNO₃, H₂SO₄, HClO₄, FSO₃H, ClSO₃H, CF₃SO₃H, various organic acids, amino acids, and the like).

Examples of the electron acceptor compound include TCNQ (tetracyanoquinodimethane), tetrafluorotetracyanoquinodimethane, tetracyanoquinodimethane halides, 1,1-dicyanovinylene, 1,2-tricyanovinylene, benzoquinone, pentafluorophenol, dicyanofluorenone, cyanofluoroalkylsulfonylfluorenones, pyridine, pyrazine, triazine, tetrazine, pyridopyrazine, benzothiadiazole, heterocyclic thiadiazoles, porphyrin, phthalocyanine, boron quinolate compounds, boron diketonate compounds, boron diisoindomethene compounds, carborane compounds, other boron atom-containing compounds, and the electron acceptor compounds described in Chemistry Letters. 1991, p. 1707-1710.

According to the invention, it is not essential to use these dopants; however, when a dopant is used, a further enhancement of the thermoelectric conversion characteristics can be expected due to an increase in the electrical conductivity, which is preferable. In the case of using a dopant, the dopant compounds can be used singly or in combination of two or more kinds thereof. The amount of use of the dopant is preferably more than 0 parts by mass but 80 parts by mass or less, more preferably more than 0 parts by mass but 60 parts by mass or less, even more preferably 2 parts by mass to 50 parts by mass, and still more preferably 5 parts by mass to 40 parts by mass, relative to 100 parts by mass of the conjugated polymer.

From the viewpoint of enhancing the dispersibility or film-forming properties of the thermoelectric conversion material, among the dopants described above, it is preferable to use an onium salt compound. An onium salt compound is neutral in a state before acid release, but the onium salt compound is decomposed when energy such as light or heat is applied thereto and generates an acid. A doping effect is exhibited by this acid. Therefore, after the thermoelectric conversion material is molded and processed into a desired shape, doping is implemented by light irradiation or the like, and a doping effect can be exhibited. Furthermore, since the onium salt compound is neutral before acid release, various components such as the conjugated polymer and the electroconductive nanomaterial are uniformly dissolved or dispersed in the thermoelectric conversion material without causing aggregation, precipitation or the like of the conjugated polymer. Due to this uniform dissolvability or dispersibility of this thermoelectric conversion material, the thermoelectric conversion material can exhibit excellent electrically conductive properties after doping. Furthermore, since satisfactory coatability or film-forming properties are obtained, excellent moldability/processability of the thermoelectric conversion layer and the like is obtained.

<Other Components>

The thermoelectric conversion material of the invention may also contain an oxidation inhibitor, a light-fast stabilizer, a heat-resistant stabilizer, a plasticizer and the like, in addition to the components described above.

Examples of the oxidation inhibitor include IRGANOX 1010 (manufactured by Ciba Geigy Japan, Ltd.), SUMILIZER GA-80 (manufactured by Sumitomno Chemical Co., Ltd.), SUMILIZER GS (manufactured by Sumitomo Chemical Co., Ltd.), and SUMILIZER GM (manufactured by Sumitomo Chemical Co., Ltd.). Examples of the light-fast stabilizer include TINUVIN 234 (manufactured by BASF SE), CHIMASSORB 81 (manufactured by BASF SE), and CYASORB UV-3853 (manufactured by Sun Chemical Co., Ltd). Examples of the heat-resistant stabilizer include IRGANOX 1726 (manufactured by BASF SE), Examples of the plasticizer include ADEKA CIZER RS (manufactured by Adeka Corp.).

The mixing ratio of the other components is preferably 5% by mass or less, and more preferably 0% by mass to 2% by mass, relative to the total solid content of a preliminary mixture.

<Production of Thermoelectric Conversion Material>

The thermoelectric conversion material of the invention can be produced by mixing the various components described above. Preferably, the thermoelectric conversion material is produced by mixing the electroconductive nanomaterial, the polymer compound, and various optional components in a dispersing medium, and thereby dissolving or dispersing the various components. At this time, regarding the various components in the thermoelectric conversion material, it is preferable that the electroconductive nanomaterial is in a dispersed state, while the polymer compound and other component such as a polymer binder are dispersed or dissolved, and it is more preferable that components other than the electroconductive nanomaterial are in a dissolved state. When components other than electroconductive nanomaterial are in a dissolved state, this is preferable because an effect of suppressing a decrease in electrical conductivity caused by grain boundaries can be obtained. Meanwhile, a dispersed state refers to a state of molecules existing as aggregates having a particle size to the extent that the aggregates do not settle out in a solvent even if the aggregates are stored for a long time (as a reference, one month or longer), and dispersibility of the thermoelectric conversion material can be evaluated by this aggregated state. Furthermore, a dissolved state refers to a state in which a material is solvated in a state of existing as individual molecules in a solvent.

There are no particular limitations on the method for producing a thermoelectric conversion material, and production can be carried out at normal temperature and normal pressure, using a conventional mixing apparatus or the like. For example, the thermoelectric conversion material may be produced by dissolving or dispersing various components by stirring, shaking or kneading the various components in a solvent. In order to promote dissolution or dispersion, an ultrasonication treatment may be performed.

Furthermore, the dispersibility of the electroconductive nanomaterial can be increased by heating the solvent to a temperature of from room temperature to the boiling point in the dispersing process, prolonging the dispersing time, or increasing the application intensity of stirring, shaking, kneading, ultrasonication, or the like.

[Thermoelectric Conversion Element]

The thermoelectric conversion element of the invention has a first electrode, a thermoelectric conversion layer, and a second electrode on a substrate, and the thermoelectric conversion layer contains an electroconductive nanomaterial and a polymer compound.

It is desirable that the thermoelectric conversion element of the invention has a first electrode, a thermoelectric conversion layer, and a second electrode on a substrate, and there are no particular limitations on other configurations such as the positional relationship between the first electrode and the second electrode, and the thermoelectric conversion layer. In the thermoelectric conversion element of the invention, it is desirable that the thermoelectric conversion layer is disposed so as to be in contact with the first electrode and the second electrode on at least one surface of the thermoelectric conversion layer. For example, it is an acceptable embodiment that the thermoelectric conversion layer is sandwiched between the first electrode and the second electrode. In this case, the thermoelectric conversion element of the invention has a first electrode, a thermoelectric conversion layer, and a second electrode in this order on a substrate. Furthermore, it is also an acceptable embodiment that the thermoelectric conversion layer is disposed so as to be in contact with the first electrode and the second electrode on either surface thereof. In this case, the thermoelectric conversion element of the invention has a thermoelectric conversion layer laminated on the first electrode and the second electrode that are formed to be separated apart from each other on a substrate.

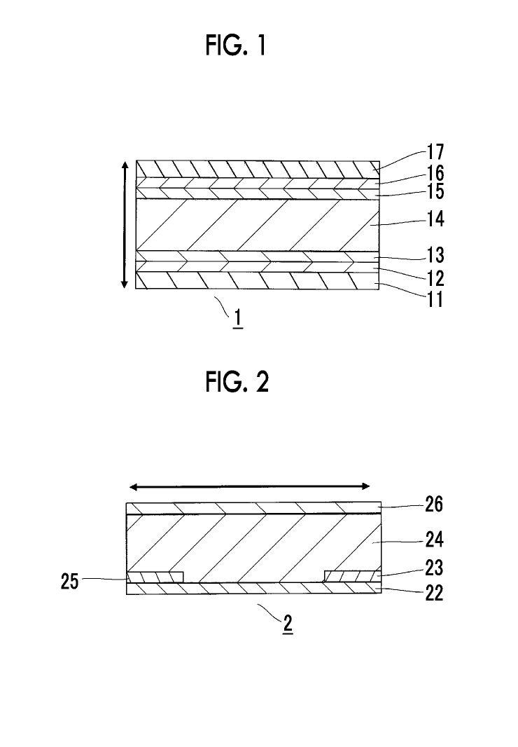

As an example of the thermoelectric conversion element of the invention, the structure of the element illustrated in FIG. 1 and FIG. 2 may be mentioned. In FIG. 1 and FIG. 2, the arrow indicates the direction of temperature difference at the time of use of the thermoelectric conversion element.

The thermoelectric conversion element 1 illustrated in FIG. 1 includes a pair of electrodes including a first electrode 13 and a second electrode 15, and a thermoelectric conversion layer 14 formed from the thermoelectric conversion material of the invention between the electrodes 13 and 15, on a first substrate 12. Disposed on the other surface of the second electrode 15 is a second substrate 16. On the outside of the first substrate 12 and the second substrate 16, metal plates 11 and 17 are disposed so as to face each other. The metal plates 11 and 17 are not particularly limited and are formed from metal materials that are conventionally used in thermoelectric conversion elements.

In regard to the thermoelectric conversion element of the invention, it is preferable that a thermoelectric conversion layer is provided in a membrane (film) form from the thermoelectric conversion material of the invention, on a substrate with an electrode interposed therebetween, and this substrate is caused to function as the first substrate 12. That is, it is preferable that the thermoelectric conversion element 1 has a structure in which a first electrode 13 or a second electrode 15 is provided on the surfaces of two sheets of substrates 12 and 16 (surface on which a thermoelectric conversion layer 14 is formed), and a thermoelectric conversion layer 14 formed using the thermoelectric conversion material of the invention is provided between these electrodes 13 and 15.

In the thermoelectric conversion element 2 illustrated in FIG. 2, a first electrode 23 and a second electrode 25 are disposed on a first substrate 22, a thermoelectric conversion layer 24 is formed so as to cover both the first electrode 23 and the second electrode 25, and a second substrate 26 is provided on this thermoelectric conversion layer 24. The thermoelectric conversion element 2 is the same as the thermoelectric conversion element 1, except for the positions of disposition of the first electrode and the second electrode, and the presence or absence of a metal plate.

The thermoelectric conversion layer 14 of the thermoelectric conversion element 1 is such that one surface thereof is covered by the first substrate 12, with the first electrode 13 interposed therebetween. Furthermore, the thermoelectric conversion layer 24 of the thermoelectric conversion element 2 is such that one surface thereof is covered by the first electrode 23, the second electrode 25, and the first substrate 22. It is preferable to compress the second substrate 16 or 26 also on the other surface of the thermoelectric conversion layer 14 or 24, from the viewpoint of protecting the thermoelectric conversion layer 14 and 24. In this case, the second substrate 16 or 26 may be compressed on the thermoelectric conversion layer 14 or 24, with the second electrode 15 interposed therebetween. That is, it is preferable that the second electrode 15 is formed in advance on the surface of the second substrate 16 (compressed surface of the thermoelectric conversion layer 14) used in the thermoelectric conversion element 1. Furthermore, the second substrate 16 or 26 may also be compressed on the thermoelectric conversion layers 14 or 24 without having the electrode 15 interposed therebetween. In regard to the thermoelectric conversion elements 1 and 2, it is preferable to perform the compression of the electrode and the thermoelectric conversion layer by heating the system to about 100° C. to 200° C., from the viewpoint of increasing adhesiveness.

Regarding the substrate of the thermoelectric conversion element of the invention, and the first substrates 12 and 22, and the second substrates 16 and 26 in the thermoelectric conversion elements 1 and 2, a substrate formed from glass, transparent ceramics, metals, plastic films, and the like can be used. In the thermoelectric conversion element of the invention, it is preferable that the substrate has flexibility, and specifically, it is preferable that the substrate has flexibility such that the endurable number of cycles in a bending test, MIT, according to the measurement method defined in ASTM D2176 is 10,000 cycles or more. Such a substrate having flexibility is preferably a plastic film, and specific examples thereof include polyester films such as films of polyesters such as polyethylene terephthalate, polyethylene isophthalate, polyethylene naphthalate, polybutylene terephthalate, poly(1,4-cyclohexylene dimethylene terephthalate), polyethylene-2,6-phthalene dicarboxylate, and a polyester between bisphenol A and iso- and terephthalic acid; polycycloolefin films such as a ZEONOR film (trade name, manufactured by Zeon Corp.), an ARTON film (trade name, manufactured by JSR Corp.), and SUMILITE FS1700 (trade name, manufactured by Sumitomo Bakelite Co., Ltd.): polyimide films such as CAPTON (trade name, manufactured by DuPont-Toray Co., Ltd.), APICAL (trade name, manufactured by Kaneka Corp.), UPILIEX (trade name, manufactured by Ube Industries, Ltd.), and POMIRAN (trade name, manufactured by Arakawa Chemical Industries, Ltd.); polycarbonate films such as PURE-ACE (trade name, manufactured by Teijin Chemicals, Ltd.) and ELMECH (trade name, manufactured by Kaneka Corp.); polyether ether ketone films such as SUMILITE FS1100 (trade name, manufactured by Sumitomo Bakelite Co., Ltd); and polyphenyl sulfide films such as TORELINA (trade name, manufactured by Toray Industries, Inc.). The substrate may be appropriately selected according to the usage conditions or environment; however, from the viewpoints of easy availability, and preferably from the viewpoints of heat resistance to a temperature of 100° C. or higher, economic efficiency, and effectiveness, commercially available films of polyethylene terephthalate, polyethylene naphthalate, various polyimides, polycarbonates and the like are preferred.

Particularly it is preferable to use a substrate having an electrode provided on the surface compressed with the thermoelectric conversion layer. Regarding the electrode material that forms the first electrode and the second electrode provided on this substrate, transparent electrodes such ITO and ZnO; metal electrodes such as silver, copper, gold, and aluminum; carbon materials such as CNT and graphene; organic materials such as PEDOT/PSS; electroconductive pastes having electroconductive microparticles of silver, carbon and the like dispersed therein; and electroconductive pastes containing metal nanowires of silver, copper, aluminum and the like, can be used. Among these, the electrode material is preferably aluminum, gold, silver, or copper. At this time, the thermoelectric conversion element 1 is configured to include a substrate 11, a first electrode 13, a thermoelectric conversion layer 14, and a second electrode 15 in this order, and the outer side of the second electrode 15 may adjoin a second substrate 16, or the second electrode 15 may be exposed to air as the outermost surface, without having a second substrate 16 provided thereon. Furthermore, the thermoelectric conversion element 2 is configured to include a substrate 22, a first electrode 23, a second electrode 25, and a thermoelectric conversion layer 24 in this order, and the outer side of the thermoelectric conversion layer 24 may adjoin a second substrate 26, or the thermoelectric conversion layer 24 may be exposed to air as the outermost surface, without having a second substrate 26 provided thereon.

The thickness of the substrate is preferably 30 μm to 3,000 μm, more preferably 50 μm to 1,000 μm even more preferably 100 μm to 1,000 μm, and particularly preferably 200 μm to 800 μm, from the viewpoints of thermal conductivity, handleability, prevention of damage to the thermoelectric conversion layer caused by external impacts, and the like.

The thermoelectric conversion layer of the thermoelectric conversion element of the invention is formed from the thermoelectric conversion material of the invention, and in addition to this, it is preferable that the thermoelectric conversion layer contains the polymer binder described above, and may also contain a dopant or a decomposition product thereof, a metal element, and other components. These components and the content ratios thereof in the thermoelectric conversion layer are as described above.

In regard to the thermoelectric conversion element of the invention, the carrier concentration of the thermoelectric conversion layer is preferably 1×10²³ to 1×10²⁶ carriers/m³, and more preferably 1×10²⁴ to 5×10²⁵ carriers/m³. It is generally known that the carrier concentration of a material affects the thermoelectric conversion performance of the material, and when the carrier concentration of the thermoelectric conversion layer is within the range described above, satisfactory thermoelectric conversion performance can be achieved, which is preferable. When a thermoelectric conversion layer is formed using the thermoelectric conversion material of the invention, the above-mentioned carrier concentration can be achieved.

The carrier concentration of the thermoelectric conversion layer can be measured using an Electron Spin Resonance (ESR) analysis method. For the ESR analysis, for example, a BRULTKER ESR EMXplus type apparatus (manufactured by Hitachi High-Technologies Corp.) can be used.

The layer thickness of the thermoelectric conversion layer is preferably 0.1 μm to 1,000 μm, and more preferably 1 μm to 100 μm. When the film thickness is adjusted to this range, a temperature difference can be easily applied, and an increase in the resistance in the film can be prevented.

Generally, in regard to the thermoelectric conversion element, an element can be conveniently produced, as compared to photoelectric conversion elements such as an element for organic thin film solar cells. Particularly, when the thermoelectric conversion material of the invention is used, since it is not necessary to consider the light absorption efficiency as compared to elements for organic thin film solar cells, formation of a thick film having a film thickness of about 100 times to 1000 times is enabled, and chemical stability against oxygen or moisture in air is enhanced.

The method for applying the thermoelectric conversion material is not particularly limited, and for example, known coating methods such as spin coating, extrusion die coating, blade coating, bar coating, screen printing, stencil printing, roll coating, curtain coating, spray coating, dip coating, and an inkjet printing method can be used. Among these, particularly, screen printing is particularly preferred from the viewpoint of obtaining excellent adhesiveness of the thermoelectric conversion layer to the electrode, and an inkjet printing method is particularly preferred from the viewpoint of obtaining excellent film forming properties of the thermoelectric conversion layer.

After the thermoelectric conversion material is applied, if necessary, the dispersing medium or the like may be distilled off by providing a heating process or a drying process. For example, the coating film of the thermoelectric conversion material can be dried by volatilizing the solvent by performing heated drying or blowing hot air.

(Doping by Energy Application)

When the thermoelectric conversion material contains the above-mentioned onium salt compound as a dopant, it is preferable to increase the electrically conductive properties by forming a film, and then performing a doping treatment by irradiating the film with active energy radiation or heating the film. Through this treatment, an acid is generated from the onium salt compound, and as this acid protonates the conjugated polymer, the conjugated polymer is doped with positive charges (p-type doping).

Active energy radiation includes radiation and electromagnetic waves, and the radiation includes particle beams (high-speed particle beams) and electron beams. Examples of the particle beams include charged particle beams such as alpha radiation (α-rays), beta radiation (β-rays), a proton beam, an electron beam (refers to a beam obtained by accelerating electrons with an accelerator without utilizing nuclear decay), and a deuteron beam; and uncharged particle beams such as a neutron beam and cosmic rays. Examples of the electron radiation include gamma radiation (γ-rays), and X-radiation (X-rays, soft X-rays). Examples of the electromagnetic waves include radio waves, infrared radiation, visible light, ultraviolet radiation (near-ultraviolet radiation, far-ultraviolet radiation, and extreme ultraviolet radiation), X-radiation, and gamma radiation. The radiation used for the invention is not particularly limited, and for example, electromagnetic waves having a wavelength near the maximum absorption wavelength of the onium salt compound (acid generator) used may be appropriately selected.

Among these active energy radiations, preferred examples from the viewpoints of the doping effect and safety are ultraviolet radiation, visible light, and infrared radiation, and specifically, a light radiation having a maximum emission wavelength at 240 nm to 1100 nm, preferably at 240 nm to 850 nm, and more preferably at 240 nm to 670 nm, is preferred.

For the irradiation with active energy radiation, a radiation or electromagnetic waves irradiation apparatus is used. The wavelength of the radiation or electromagnetic waves is not particularly limited, and any apparatus capable of emitting a radiation or electromagnetic waves having a wavelength in the region corresponding to the response wavelength of the onium salt compound used, may be selected.

Examples of the apparatus that can emit radiation or electromagnetic waves include light exposure apparatuses which use a LED lamp; a mercury lamp such as a high pressure mercury lamp, an ultrahigh pressure mercury lamp, a deep UV lamp, or a low pressure UV lamp; a halide lamp, a xenon flash lamp, a metal halide lamp; an excimer lamp such as an ArF excimer lamp or a KrF excimer lamp; an extreme ultraviolet lamp, an electron beam, or an X-ray lamp, as a light source. Irradiation with ultraviolet radiation can be carried out using a conventional ultraviolet irradiation apparatus, for example, a commercially available ultraviolet irradiation apparatus for curing/adhesion/exposure (manufactured by Ushio, Inc., SP9-250UB or the like).

The exposure time and the amount of light may be appropriately selected in consideration of the kind of the onium salt compound used and the doping effect. Specifically, exposure may be carried out with an amount of light of 10 mJ/cm² to 10 J/cm², and preferably 50 mJ/cm² to 5 J/cm².

In a case in which doping is implemented by heating, it is desirable to heat the film thus formed to a temperature higher than or equal to the temperature at which the onium salt compound generates an acid. The heating temperature is preferably 50° C. to 200° C., and more preferably 70° C. to 150° C. The heating time is preferably 1 minute to 60 minutes, and more preferably 3 minutes to 30 minutes.

The timing for the doping treatment is not particularly limited; however, it is preferable to perform the doping treatment after the thermoelectric conversion material of the invention is subjected to a processing treatment such as film formation.

The thermoelectric conversion layer (also referred to as a thermoelectric conversion film) formed from the thermoelectric conversion material of the invention and the thermoelectric conversion element of the invention exhibit excellent thermoelectric conversion performance. Furthermore, the thermoelectric conversion layer formed from the thermoelectric conversion material of the invention becomes a uniform layer having high dispersibility of the electroconductive nanomaterial, having fewer defects such as pinholes, and having reduced performance deterioration.

Therefore, the thermoelectric conversion material of the invention is suitably used as a material for membranes (electroconductive membranes and the like) of thermoelectric conversion elements and thermoelectric power generation elements, and the thermoelectric conversion layer of the invention is suitably used as a membrane (electroconductive membranes and the like) for thermoelectric power generation elements.

The article for thermoelectric power generation of the invention uses the thermoelectric conversion element of the invention as a thermoelectric power generation element. Specifically, it is preferable to use the thermoelectric conversion element of the invention for applications such as power generators such as a hot spring thermoelectric generator, solar power generator and a waste heat thermoelectric generator, a power source for wrist watches, a semiconductor-driven power source, and a power source for (small-sized) sensors.

### EXAMPLES

Hereinafter, the invention will be explained in more detail by way of Examples, but the invention is not intended to be limited to these Examples.

The thermally excitable polymer, the electroconductive nanomaterial, the polymer binder, and the dopant of the invention used in Examples are disclosed below.

[Thermally Excitable Polymer of the Invention]

Thermally excitable polymers 1 to 12 and 101 to 107 composed of the repeating structures shown below were used. These thermally excitable polymers were synthesized by methods equivalent to the method described above.

Meanwhile, the abbreviation “Ph” represents a phenyl group. The symbol * represents a linking site of the repeating structure.

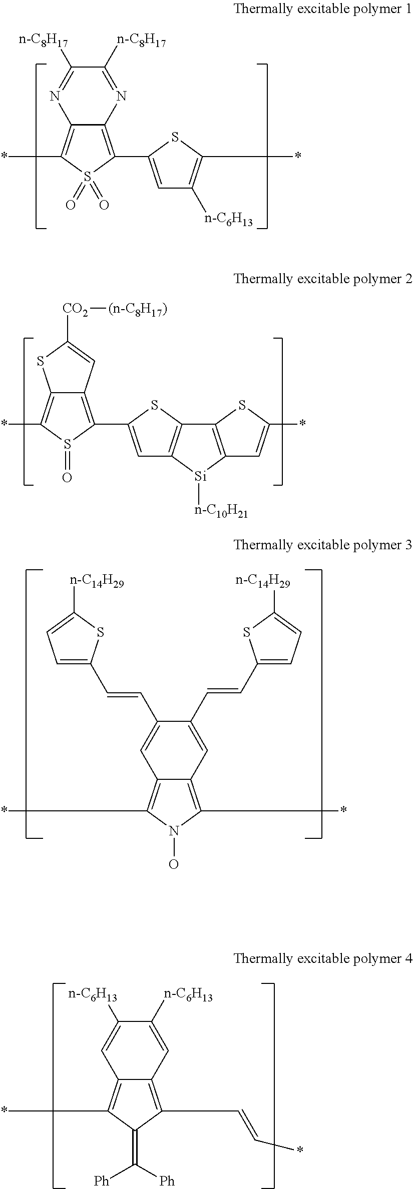

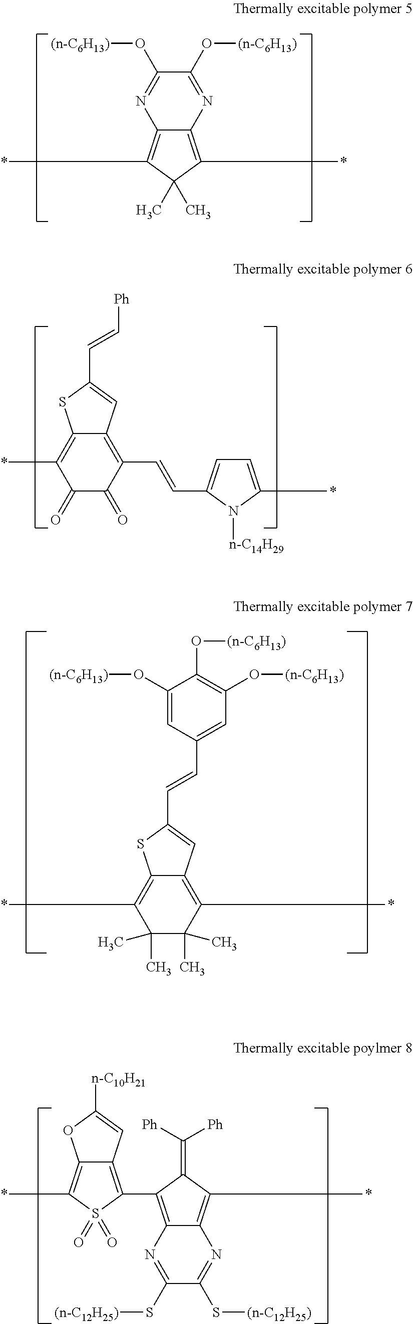

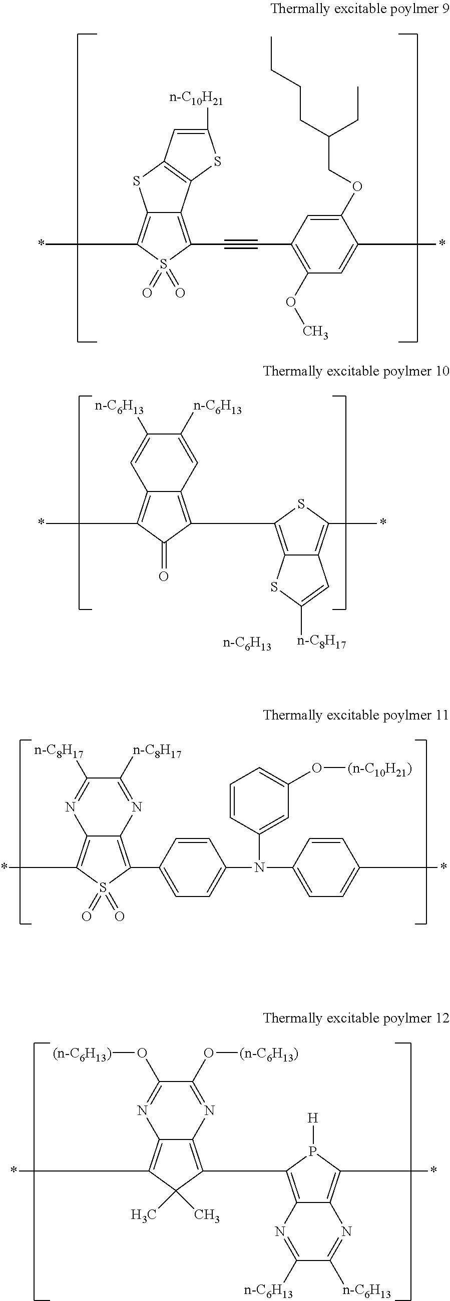

Thermally excitable polymers 101 to 107 are shown below.

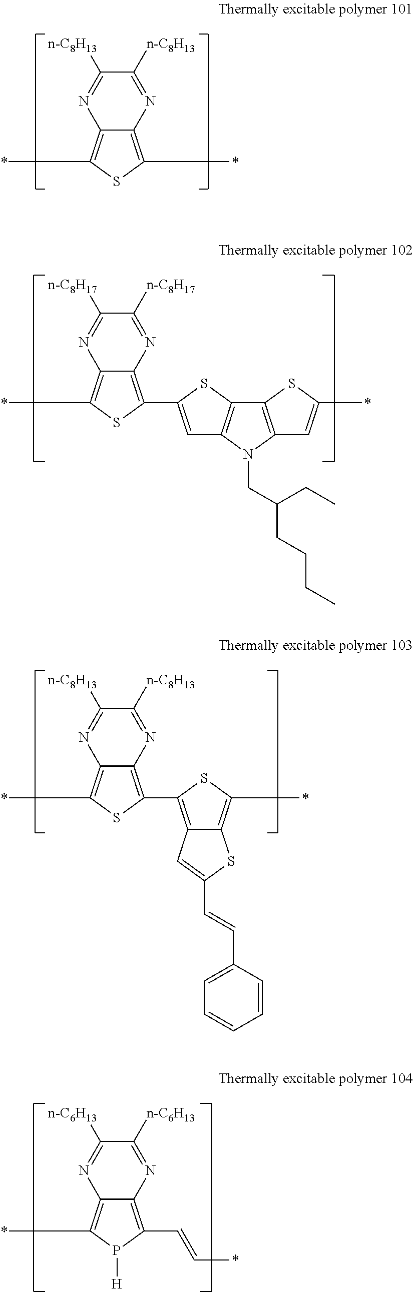

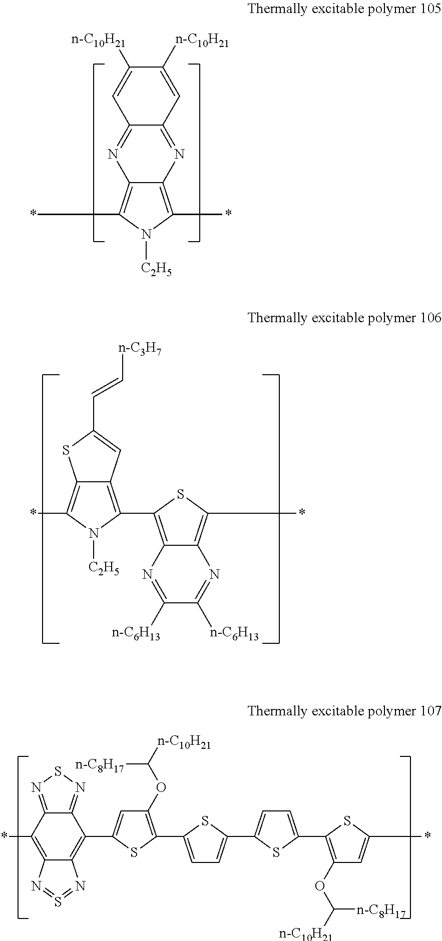

With regard to the thermally excitable polymers 1 to 12 and 101 to 107, the average inter-unit distance L (calculated value) of the ring A of the repeating unit represented by Formula (1) described above, and the optical band gap and the weight average molecular weight of each of the thermally excitable polymers are as described below.

Thermally excitable polymer 1: average inter-unit distance L (calculated value) of the ring A=1.36 Å, optical band gap=0.3 eV or less, weight average molecular weight=13,000

Thermally excitable polymer 2: average inter-unit distance L (calculated value) of the ring A=1.39 Å, optical band gap=0.7 eV, weight average molecular weight==17,000

Thermally excitable polymer 3: average inter-unit distance L (calculated value) of the ring A=1.40 Å, optical band gap=0.7 eV, weight average molecular weight=27,000

Thermally excitable polymer 4: average inter-unit distance L (calculated value) of the ring A=1.35 Å, optical band gap=0.3 eV or less, weight average molecular weight=11,000

Thermally excitable polymer 5: average inter-unit distance L (calculated value) of the ring A=1.36 Å, optical band gap=0.3 eV or less, weight average molecular weight=16,000

Thermally excitable polymer 6: average inter-unit distance L (calculated value) of the ring A=1.41 Å, optical band gap=1.0 eV, weight average molecular weight=49,000

Thermally excitable polymer 7: average inter-unit distance L (calculated value) of the ring A=1.38 Å, optical band gap=0.6 eV, weight average molecular weight=27,000

Thermally excitable polymer 8: average inter-unit distance L (calculated value) of the ring A=1.37 Å, optical band gap=0.4 eV, weight average molecular weight=20,000

Thermally excitable polymer 9: average inter-unit distance L (calculated value) of the ring A=1.40 Å, optical band gap=0.9 eV, weight average molecular weight=61,000

Thermally excitable polymer 10: average inter-unit distance L (calculated value) of the ring A=1.39 Å, optical band gap=0.8 eV, weight average molecular weight=48,000

Thermally excitable polymer 1: average inter-unit distance L (calculated value) of the ring A=1.42 Å, optical band gap=1.1 eV, weight average molecular weight=39,000

Thermally excitable polymer 12: average inter-unit distance L (calculated value) of the ring A=1.39 Å, optical band gap=0.8 eV, weight average molecular weight=16,000

Thermally excitable polymer 101: average inter-unit distance L (calculated value) of the ring A=1.42 Å, optical band gap=1.1 eV, weight average molecular weight=22,000

Thermally excitable polymer 102: average inter-unit distance L (calculated value) of the ring A=1.40 Å, optical band gap=0.9 eV, weight average molecular weight=59,000

Thermally excitable polymer 103: average inter-unit distance L (calculated value) of the ring A=1.41 Å, optical band gap=1.0 eV, weight average molecular weight=35,000

Thermally excitable polymer 104: average inter-unit distance L (calculated value) of the ring A=1.40 Å, optical band gap=0.9 eV weight average molecular weight=36,000

Thermally excitable polymer 105: average inter-unit distance L (calculated value) of the ring A=1.42 Å, optical band gap==1.1 eV, weight average molecular weight=14,000

Thermally excitable polymer 106: average inter-unit distance L (calculated value) of the ring A=1.39 Å, optical band gap=0.8 eV, weight average molecular weight=34,000

Thermally excitable polymer 107: average inter-unit distance L (calculated value) of the ring A=1.38 Å, optical band gap=0.6 eV, weight average molecular weight=32,000

<Calculation of Average Inter-Unit Distance L of Ring A>

The average inter-unit distance was calculated by the calculation method described above. That is, the interatomic distances L1 and L2 were calculated from an optimized structure by the Gaussian calculation method (name of program used: Gaussian 09 (manufactured by Gaussian, Inc), parameter used: B3LYP/6-31G*), and the average value obtained by Formula (1) described above was designated as the average inter-unit distance L (calculated value) of the ring A.

<Measurement of Optical Band Gap>

The optical band gap of each of the thermally excitable polymers was calculated by the method described below.

A thermally excitable polymer was dissolved in a dissolvable organic solvent, and the solution was applied on a UV ozone-treated quartz substrate (size: 15 mm×15 mm, thickness: 1.1 mm) by a spin coating method. The coating film was dried for one hour under vacuum conditions, thereby the residual organic solvent being distilled off, and then the absorption spectrum was measured with an ultraviolet-visible-near-infrared (UV-Vis-NIR) spectrophotometer (manufactured by Shimadzu Corporation, trade name: UV-3600). The wavelength λ5 (unit: nm) of the absorption edge on the longer wavelength side, at which the absorbance was 5% relative to the maximum value (λmax) of the absorbance, was determined, the unit of λ5 was converted, and thereby the optical band gap (unit: eV) was calculated.

<Measurement of Weight Average Molecular Weight>

The weight average molecular weight of the thermally excitable polymer was determined as a value calculated relative to polystyrene standards by gel permeation chromatography (GPC).

More specifically, o-dichlorobenzene was added to a thermally excitable polymer to dissolve the polymer at 145° C., the solution was filtered through a sintered filter having a pore size of 1.0 μm, and thus a sample solution at 0.15 w/v % was prepared. The weight average molecular weight was measured under the conditions described below.

Apparatus: “ALLIANCE GPC2000 (manufactured by Waters Corporation)”

Columns: “TSKgel GMH₆-HT”-“TSKgel GMH₆-HT”-“TSKgel GMH₆-HTL”-“TSKgel GMH₆-HTL” (all 7.5 mm I.D.×30 cm, manufactured by Tosoh Corporation)

Column temperatures: 140° C.

Detector: Differential refractometer

Mobile phase: o-dichlorobenzene

[Electroconductive Nanomaterial]

Single wall CNT: “ASP-100F” (trade name, manufactured by Hanwha Nanotech Corp., dispersion (CNT concentration: 60% by mass), average length in the major axis direction: about 5 μm to 20 μm, average diameter: about 1.0 nm to 1.2 nm)

Graphite: “AGB-5” (trade name, manufactured by Ito Graphite Co., Ltd., average length of one edge: 5 μm)

Carbon nanofibers: “VGCF-X” (trade name, manufactured by Showa Denko K.K., average length in the major axis direction: 150 nm)

Graphene: “F-GF1205-AB” (trade name, manufactured by SPI Supplies Division, Structure Probe, Inc., average length of one edge: 10 nm or more)

Carbon black: “KETJEN BLACK EC600JD” (trade name, manufactured by Lion Corp., average particle size: 10 nm or more)

Carbon nanoparticles: NANODIAMOND PL-D-G (trade name, manufactured by PlasmaChem GmbH, average particle size: 10 nm or more)

Silver nanowires: Produced based on Production Method 2 described in JP2012-230881A (average minor axis length: 23 nm, average major axis length: 32 μm)

Nickel nanotubes: Produced by the method based on Example 1 described in JP4374439B (diameter: 100 nm, length: 6 μm)

Gold nanoparticles: 741973 (product No., manufactured by Sigma-Aldrich Co. LLC., particle size: about 30 nm)

<Measurement of Length in Major Axis Direction>

The length in the major axis of an electroconductive nanomaterial was calculated by the method described below.

A dispersion liquid of an electroconductive nanomaterial in a solvent. (solvent: water, ortho-dichlorobenzene, isopropyl alcohol, or the like) was applied on a glass substrate. The coating film was dried for 10 hours at 100° C. in a vacuum, and then the coating film was peeled off from the glass substrate. This peeled off film was observed using transmission electron microscopy (TEM) or scanning electron microscopy (SEM), and the lengths in the major axis direction of 30 pieces of the electroconductive nanomaterial were measured by an image analysis. The average of these lengths was calculated.

[Polymer Binder]

1. Conjugated Polymer Binder

Binders 1 to 6 described below and PEDOT:PPS were used as conjugated polymer binders.

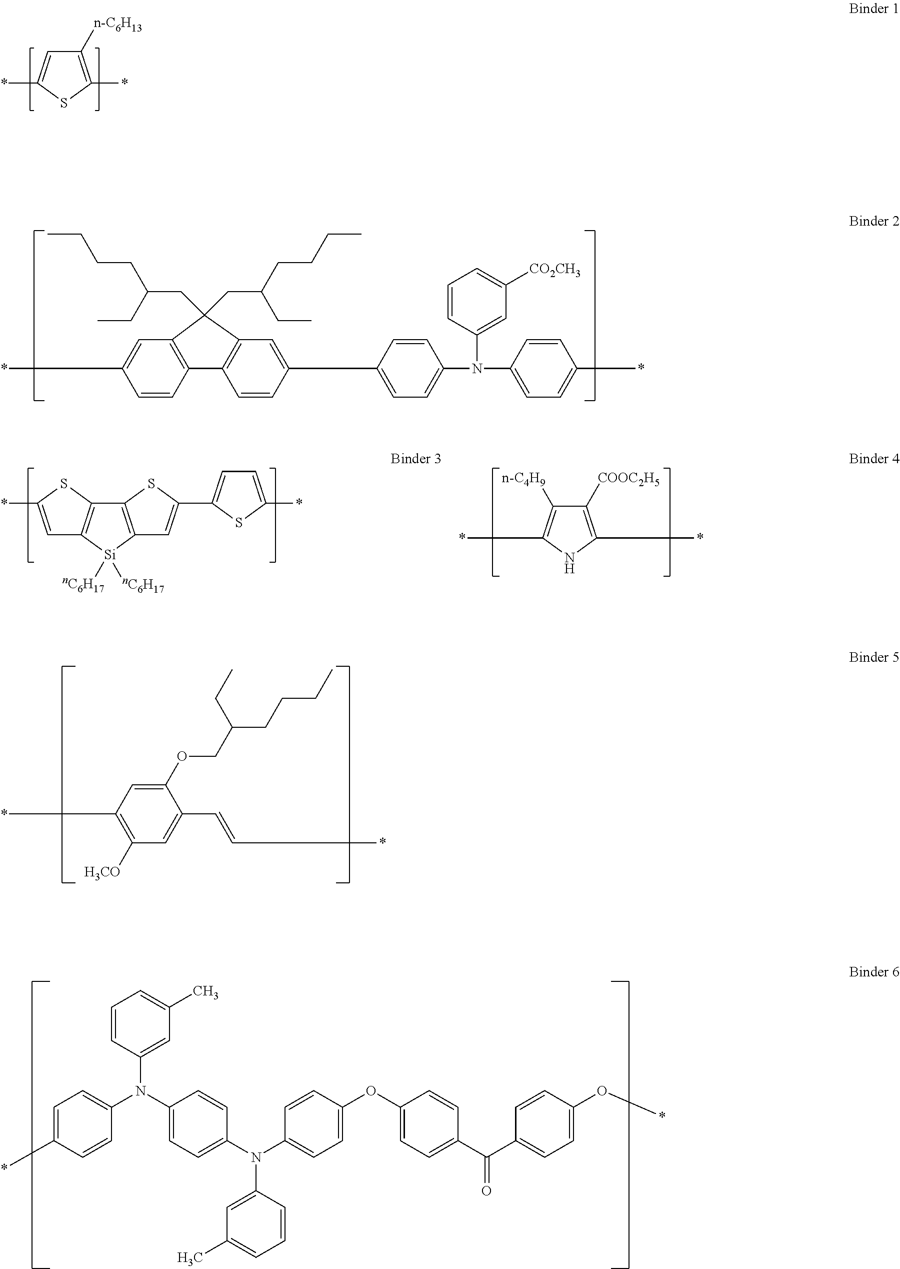

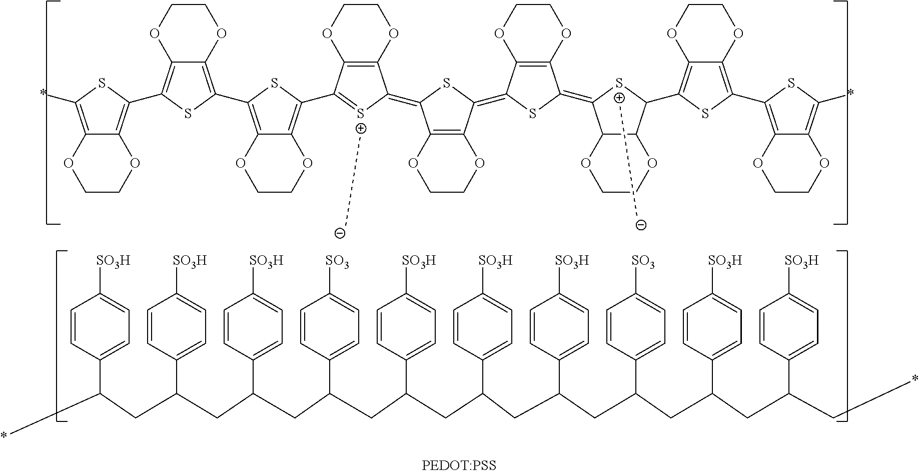

In regard to the repeating structures of the conjugated polymer binders 1 to 6 and PEDOT:PPS, the symbol * represents a linking site of the repeating structure.

The optical band gaps and the weight average molecular weights of the conjugated polymer binders 1 to 6 are as described below. The optical band gaps and the weight average molecular weights were measured in the same manner as in the case of the thermally excitable polymer.

Binder 1: Optical band gap=2.0 eV weight average molecular weight=53,000

Binder 2: Optical band gap=2.0 eV or more, weight average molecular weight=20,000

Binder 3: Optical band gap=2.1 eV, weight average molecular weight=19,000

Binder 4: Optical band gap=2.0 eV or more, weight average molecular weight=41,000

Binder 5: Optical band gap=2.0 eV or more, weight average molecular weight=34,000

Binder 6: Optical band gap=2.0 eV or more, weight average molecular weight=26,000

PEDOT:PSS: Poly(3,4-ethylenedioxythiophene)-poly(styrene sulfonate), manufactured by H.C. Starck GmbH, trade name “BAYTRON P”, aqueous dispersion at a concentration of about 1.3% by mass of PEDOT/PSS), PEDOT/PSS (mass ratio)=1/2.5, optical band gap=about 0 eV

<Synthesis Example of Conjugated Polymer Binder 2>

The conjugated polymer binder 2 was synthesized as described below.

9-(2-Ethylhexyl)-9-(2-ethylpentyl)-2,7-bis(trimethylstannyl)-9H-fluorene (3.08 g, 4.38 mmol), methyl 3-(bis(4-bromophenyl)amino)benzoate (2.02 g, 4.38 mmol), and tetrakis(triphenylphosphine)palladium (253 mg, 0.219 mmol) were introduced into a 200-mL flask, and the vessel was purged with nitrogen. Toluene (35 mL) and N,N-dimethylformamide (9 mL) as solvents were introduced into this vessel using a syringe, and then the mixture was allowed to react by heating and stirring the system for 24 hours in an oil bath at 120° C. in a nitrogen atmosphere. The reaction liquid was cooled to room temperature, and then the reaction liquid was filtered through Celite to remove any insoluble components. The filtrate thus obtained was added dropwise in small amounts into methanol, solids were precipitated, and then the solids were preparatively isolated by filtration. These solids were heated and washed for 10 hours with acetone solvent using a Soxhlet extractor, and thus impurities were removed. Finally, these solids were dried for 10 hours in a vacuum, and thereby the intended conjugated polymer binder 2 was obtained (amount obtained: 2.21 g, yield: 73%).

2. Non-Conjugated Polymer Binder

Polymers described below were used as non-conjugated polymer binders.

Polystyrene: 430102 (product No., manufactured by Sigma-Aldrich Co. LLC., weight average molecular weight=192,000)

Polymethyl methacrylate: manufactured by Wako Pure Chemical Industries, Ltd.

Polyvinyl acetate: manufactured by Wako Pure Chemical Industries, Ltd.

Polylactic acid: PLA-0015 (trade name, manufactured by Wako Pure Chemical Industries, Ltd.)

Polyvinylpyrrolidone: manufactured by Wako Pure chemical Industries, Ltd.

Polyimide: SOLPIT-6,6-PI (trade name, manufactured by Solpit industries, Ltd.)

Polycarbonate: IUPIZETA PCZ-300 (trade name, manufactured by Mitsubishi Gas Chemical Company, Inc.)

[Dopant]

Compounds 1 to 4 described below were used as dopants.

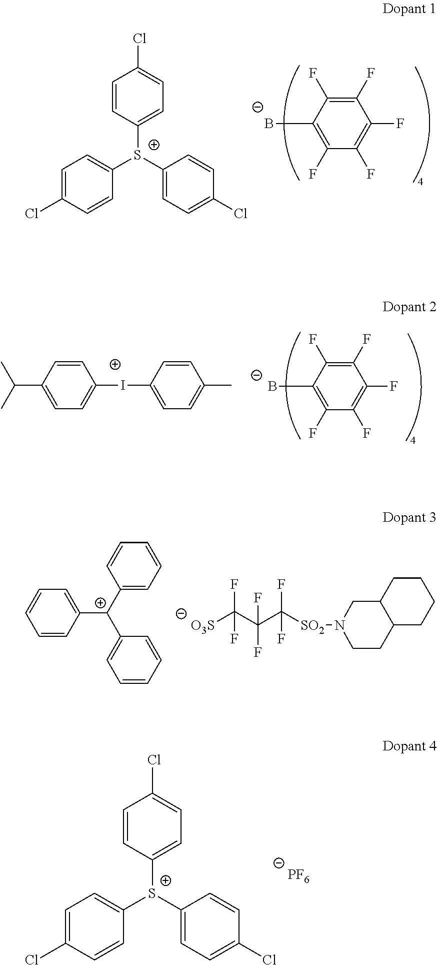

### Example 1

6 mg of the thermally excitable polymer 1 and 4 mg of the single wall CNT (calculated relative to the CNT concentration) were added to 4.0 mL of ortho-dichlorobenzene, and the mixture was dispersed for 40 minutes at 35° C. in an ultrasonic water bath with a temperature control function (manufactured by SND Co., Ltd., US-10KS). Thus, a dispersion liquid as a thermoelectric conversion material was prepared. This dispersion liquid was applied by a screen printing method onto a glass substrate 12 (thickness: 0.8 mm) having gold (thickness: 20 nm, width: 5 mm) as a first electrode 13 on one surface, the dispersion liquid being applied on the electrode 13 surface, and the assembly was heated for 45 minutes at 80° C. to remove the solvent. Thereafter, the assembly was dried for 10 hours in a vacuum at room temperature, and thereby, a thermoelectric conversion layer 14 having a film thickness of 2.2 μm and a size of 8 mm×8 mm was formed. Subsequently, a glass substrate 16 having gold deposited thereon as a second electrode 15 (thickness of electrode 15: 20 nm, width of electrode 15: 5 mm, thickness of glass substrate 16: 0.8 mm) was bonded on top of the thermoelectric conversion layer 14 at 80° C. such that the second electrode 15 faced the thermoelectric conversion layer 14, and thereby a thermoelectric conversion element 101 of the invention, which corresponds to the thermoelectric conversion element 1 illustrated in FIG. 1, was produced.

Thermoelectric conversion elements 102 to 119 of the invention and comparative thermoelectric conversion elements c101 to c105 were produced in the same manner as in the case of the thermoelectric conversion element 101, except that the thermally excitable polymer, the electroconductive nanomaterial, and the electrode materials were changed as indicated in the following Table 1.

[Evaluation of Dispersibility of Electroconductive Nanomaterial]

Dispersibility of the electroconductive nanomaterial (single wall CNT) in the ultrasonically dispersed dispersion liquid obtained as described above, was evaluated as follows. The results are presented in Table 1.

Measurement was made in the range of 0.1 μm to 2,000 μm using a MicroTrac MT3300 type laser diffraction scattering type particle size distribution analyzer (manufactured by Nikkiso Co., Ltd.), and the volume average particle size at which the 50% cumulative frequency was obtained (D50) was calculated. From this value of the volume average particle size, dispersibility of the single wall CNT was rated into five grades, from A to E, as described below. For practical use, it is preferable that the dispersibility satisfies the criteria of A to C.

A: The volume average particle size is less than 150 nm.

B: The volume average particle size is 150 nm or more but less than 300 nm.

C: The volume average particle size is 300 nm or more but less than 600 nm.

D: The volume average particle size is 600 nm or more, but precipitates or aggregates cannot be recognized by visual inspection.

E: Precipitates or aggregates can be visually recognized.

[Measurement of Thermoelectric Characteristic Value (Thermoelectromotive Force S)]

For each of the thermoelectric conversion elements, the thermoelectric characteristic value (thermoelectromotive force S) was evaluated by the method described below. The results are presented in Table 1.

The first electrode 13 of each thermoelectric conversion element was disposed on a hot plate that had been maintained at a constant temperature, and a Peltier device for temperature control was disposed on the second electrode 15. By decreasing the temperature of the Peltier device while the temperature of the hot plate was maintained constant (100° C.), a temperature difference (in the range of more than 0 K but no more than 4 K) was applied between the two electrodes. At this time, the thermoelectromotive force S (μV/K) per unit temperature difference was calculated by dividing the thermoelectromotive force (μV) generated between the two electrodes by the particular temperature difference (K) generated between the two electrodes, and this value was designated as the thermoelectric characteristic value of the thermoelectric conversion element. The thermoelectric characteristic value thus calculated is presented in Table 1 as a relative value with respect to the calculated value for the comparative thermoelectric conversion element c01.

TABLE 1

| Thermoelectric | Thermally | | | Dispersibility of | Thermoelectric | |
|---|---|---|---|---|---|---|
| conversion element | excitable | Electrocanductive | Electrode | electroconductive | characteristic value | |
| No. | polymer | nanomaterial | material | nanomaterial | (relative value) | Remarks |
| 10 | 1 | Single Wall CNT | Gold | A | 534 | This invention |
| 102 | 2 | Single Wall CNT | Gold | A | 450 | This invention |
| 103 | 3 | Single Wall CNT | Gold | A | 462 | This invention |
| 104 | 4 | Single Wall CNT | Gold | A | 549 | This invention |
| 105 | 5 | Single Wall CNT | Aluminum | A | 507 | This invention |
| 106 | 6 | Single Wall CNT | Silver | A | 385 | This invention |
| 107 | 7 | Single Wall CNT | ITO | A | 438 | This invention |
| 108 | 8 | Single Wall CNT | Gold | A | 490 | This invention |
| 109 | 9 | Single Wall CNT | Gold | A | 397 | This invention |
| 110 | 10 | Single Wall CNT | Aluminum | A | 426 | This invention |
| 111 | 11 | Single Wall CNT | Copper | A | 393 | This invention |
| 112 | 12 | Single Wall CNT | Gold | A | 411 | This invention |
| 113 | 101 | Single Wall CNT | Aluminum | B | 319 | This invention |
| 114 | 102 | Single Wall CNT | Gold | A | 354 | This invention |
| 115 | 103 | Single Wall CNT | Silver | A | 361 | This invention |
| 116 | 104 | Single Wall CNT | Gold | B | 398 | This invention |
| 117 | 105 | Single Wall CNT | Gold | A | 328 | This invention |
| 118 | 106 | Single Wall CNT | Gold | A | 341 | This invention |
| 119 | 107 | Single Wall CNT | Gold | B | 413 | This invention |
| c101 | Binder 1 | Single Wall CNT | Gold | C | 100 (Reference) | Comparative Example |
| c102 | Binder 6 | None | Aluminum | — | Detection limit or below | Comparative Example |
| c103 | PEDOT:PSS | Single Wall CNT | Gold | D | 136 | Comparative Example |
| c104 | 1 | None | Gold | — | Detection limit or below | Comparative Example |
| c105 | 8 | None | Gold | — | Detection limit or below | Comparative Example |

As is obvious from Table 1, the thermoelectric conversion elements 101 to 119 of the invention, each of which contained an electroconductive material having an average length in the major axis direction of at least 5 nm and the polymer compound of the invention, all had high thermoelectromotive force S, and also exhibited excellent dispersibility of the electroconductive nanomaterial.

On the contrary, the comparative thermoelectric conversion elements c101 to c105, each of which did not contain at least one of the electroconductive nanomaterial and the polymer compound of the invention, had low-thermoelectromotive forces, and the dispersibility of the electroconductive nanomaterial did not satisfy the criteria for acceptance of the invention.

### Example 2

4 mg of the thermally excitable polymer 1, 2 mg of the single wall CNT (calculated relative to the CNT concentration), and 4 mg of polystyrene as a polymer binder were added to 4.0 mL of ortho-dichlorobenzene, and the mixture was dispersed for 40 minutes in an ultrasonic water bath. This dispersion liquid was applied by a screen printing method onto a glass substrate 12 (thickness: 0.8 mm) having gold (thickness: 20 nm, width: 5 mm) as a first electrode 13 on one surface, the dispersion liquid being coated on the electrode 13 surface, and the assembly was heated for 45 minutes at 80° C. to remove the solvent. Thereafter, the assembly was dried for 10 hours in a vacuum at room temperature, and thereby, a thermoelectric conversion layer 14 having a film thickness of 2.1 m and a size of 8 mm×8 mm was formed. Subsequently, a glass substrate 16 having gold deposited thereon as a second electrode 15 (thickness of electrode 15: 20 nm, width of electrode 15: 5 mm, thickness of glass substrate 16: 0.8 mm) was bonded on top of the thermoelectric conversion layer 14 at 80° C. such that the second electrode 15 faced the thermoelectric conversion layer 14, and thereby a thermoelectric conversion element 201 of the invention, which corresponds to the thermoelectric conversion element 1 illustrated in FIG. 1, was produced.

Thermoelectric conversion elements 202 to 214 of the invention and a comparative thermoelectric conversion element c201 were produced in the same manner as in the case of the thermoelectric conversion element 201, except that the thermally excitable polymer, the polymer binder, and the electroconductive nanomaterial were changed as indicated in the following Table 2.

Meanwhile, for the thermoelectric conversion element 212, the use ratio (mass ratio) of the binder 2 and the polycarbonate was 50:50.

Dispersibility of the electroconductive nanomaterial was evaluated in the same manner as in Example 1, and the thermoelectric characteristic value (thermoelectromotive force S) was measured. The thermoelectric characteristic value (thermoelectromotive force S) indicated in Table 2 is a relative value with respect to the calculated value for the comparative thermoelectric conversion element c101 produced in Example 1. The results are presented in Table 2.

TABLE 2

| Thermoelectric | Thermally | | | Dispersibility of | Thermoelectric | |
|---|---|---|---|---|---|---|
| conversion | excitable | Polymer | Ellectroconduclive | electrocenductive | characteristic value | |
| element No. | polymer | binder | nanomaterial | nanomaterial | (relative value) | Remarks |
| 201 | 1 | Polystyrene | Carbon black | A | 556 | This invention |
| 202 | 2 | Polylactic acid | Graphite | A | 477 | This invention |
| 203 | 3 | Binder 2 | Graphene | A | 480 | This invention |
| 204 | 3 | Polymethyl methactylate | Carbon black | A | 468 | This invention |
| 205 | 3 | Binder 4 | Carbon nanofibers | A | 471 | This invention |
| 206 | 4 | Binder 1 | Single Wall CNT | A | 578 | This invention |
| 207 | 4 | Polyvinyl acetate | Carbon black | B | 553 | This invention |
| 208 | 5 | Binder 6 | Silver nanowires | A | 536 | This invention |
| 209 | 5 | Polyvinlpyrrolidone | Single Wall CNT | A | 584 | This invention |
| 210 | 6 | Binder 3 | Carbon nanoparticles | A | 419 | This invention |
| 211 | 6 | Polyimide | Nickel nanotubes | A | 430 | This invention |
| 212 | 6 | Binder 2, Polycarbonate | Single Wall CNT | A | 482 | This invention |
| 213 | 7 | Binder 5 | Nickel nanotubes | A | 461 | This invention |
| 214 | 8 | PEDOT:PSS | Gold nanoparticles | A | 507 | This invention |
| C201 | None | Polymethyl methacrylate | Silver nanowires | C | 72 | Comparative |
| | | | | | | Example |

As is obvious from Table 2, the thermoelectric conversion elements 201 to 214 of the invention, each of which contained an electroconductive nanomaterial having an average length in the major axis direction of at least 5 nm and the polymer compound of the invention, all had high thermoelectromotive force, and also exhibited excellent dispersibility of the electroconductive nanomaterial.

On the contrary, the comparative thermoelectric conversion element c201 that did not contain the polymer compound of the invention had low thermoelectromotive forces even if the thermoelectric conversion element contained a polymer binder, and the dispersibility of the electroconductive nanomaterial did not satisfy the criteria for acceptance of the invention.

### Example 3

4 mg of the thermally excitable polymer 1, 4 mg of the single wall CNT (calculated relative to the CNT concentration), and 2 mg of the dopant 1 were added to 4.0 mL of ortho-dichlorobenzene, and the mixture was dispersed for 40 minutes in an ultrasonic water bath. This dispersion liquid was applied by a screen printing method on a glass substrate 12 (thickness: 0.8 mm) having gold (thickness: 20 nm, width: 5 mm) as a first electrode 13 on one surface, the dispersion liquid being coated on the electrode 13 surface, and the assembly was heated for 45 minutes at 80° C. to remove the solvent. Thereafter, the assembly was dried for 10 hours in a vacuum at room temperature, and thereby, a thermoelectric conversion layer 14 having a film thickness of 2.2 μm and a size of 8 mm×8 mm was formed. This thermoelectric conversion layer 14 was dried, and then was doped by irradiating the thermoelectric conversion layer 14 with ultraviolet radiation (amount of light: 1.06 J/cm²) using an ultraviolet irradiation apparatus (manufactured by Eye Graphics Co., Ltd., ECS-401GX). Subsequently, a glass substrate 16 having gold deposited thereon as a second electrode 15 (thickness of electrode 15: 20 nm, width of electrode 15: 5 mm, thickness of glass substrate 16: 0.8 mm) was bonded on top of the thermoelectric conversion layer 14 at 80° C. such that the second electrode 15 faced the thermoelectric conversion layer 14, and thereby a thermoelectric conversion element 301 of the invention, which corresponds to the thermoelectric conversion element 1 illustrated in FIG. 1, was produced.

Thermoelectric conversion elements 302 to 308 of the invention were produced in the same manner as in the case of the thermoelectric conversion element 301, except that the thermally excitable polymer and the dopant were changed as indicated in the following Table 3. Meanwhile, for the thermoelectric conversion element 306, the doping treatment based on ultraviolet irradiation was not carried out.

Additionally, in regard to the thermoelectric conversion elements 302 and 304, the use ratio (mass ratio) of the thermally excitable polymer, the polymer binder, the single wall CNT, and the dopant was 40:20:30:10 in both cases.

Dispersibility of the single wall CNT was evaluated in the same manner as in Example 1, and the thermoelectric characteristic value (thermoelectromotive force S) was measured. The thermoelectric characteristic value (thermoelectromotive force S) indicated in Table 3 is a relative value with respect to the calculated value for the comparative thermoelectric conversion element c101 produced in Example 1. The results are presented in Table 3.

TABLE 3

| Thermoelectric | Thermally | | | | Dispersibility of | Thermoelectric | |
|---|---|---|---|---|---|---|---|
| conversion | excitable | Polymer | Electroconductive | | electroconductive | characteristic value | |
| element No. | polymer | binder | nanomaterial | Dopant | nanomaterial | (relative value) | Remarks |
| 301 | 1 | None | Single Wall CNT | 1 | A | 603 | This invention |
| 302 | 1 | 1 | Single Wall CNT | 2 | A | 625 | This invention |
| 303 | 2 | None | Single Wall CNT | 3 | A | 511 | This invention |
| 304 | 2 | 3 | Single Wall CNT | 1 | A | 518 | This invention |
| 305 | 5 | None | Single Wall CNT | 2 | A | 540 | This invention |
| 306 | 6 | None | Single Wall CNT | Iron (III) | B | 429 | This invention |
| | | | | chloride | | | |
| 307 | 8 | None | Single Wall CNT | 4 | A | 516 | This invention |
| 308 | 107 | None | Single Wall CNT | 1 | B | 454 | This invention |

As is obvious from Table 3, the thermoelectric conversion elements 301 to 308 of the invention, each of which contained an electroconductive nanomaterial composed of particles having an average length in the major axis of at least 5 nm, and the polymer compound of the invention, all had high thermoelectromotive force values, and also exhibited excellent dispersibility of the electroconductive nanomaterial.

The present invention has been explained together with exemplary embodiments thereof. However, the present invention is not intended to be limited by any details of the description unless particularly stated otherwise, and it is considered reasonable that the invention should be construed broadly without contradicting the spirit and scope of the invention disclosed in the attached claims.

This application claims priority over JP2013-183099 filed in Japan on Sep. 4, 2013, the disclosure of which is incorporated herein by reference.

### EXPLANATION OF REFERENCES

1, 2: thermoelectric conversion element
11, 17: metal plate
12, 22: first substrate
13, 23: first electrode
14, 24: thermoelectric conversion layer
15, 25: second electrode
16, 26: second substrate

What is claimed is:

1. A thermoelectric conversion element comprising, on a substrate:
a first electrode;
a thermoelectric conversion layer; and
a second electrode,
wherein the thermoelectric conversion layer contains an electroconductive nanomaterial having an average length in the major axis direction of at least 5 nm, and a polymer compound having a repeating unit represented by the following Formula (1), and 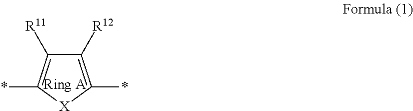
in Formula (1), ring A represents a conjugated hydrocarbon ring or a conjugated heterocyclic ring; X represents a group having one or two or more atoms selected from the group consisting of a carbon atom, an oxygen atom, a sulfur atom, a nitrogen atom, a phosphorus atom and a silicon atom, shared as ring-constituting atoms of the ring A; the average inter-unit distance of the ring A is 1.42 Å or less; R¹¹ and R¹² each independently represent a substituent, and may be bonded to each other to form a ring; and the symbol * represents a bonding position for the repeating unit.

2. The thermoelectric conversion element according to claim 1,
wherein the polymer compound has a repeating unit represented by the following Formula (2), and 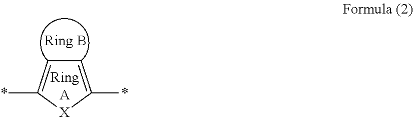
in Formula (2), ring B represents an aromatic ring; ring B may have a substituent, and may have an aromatic hydrocarbon ring or an aromatic heterocyclic ring fused thereto; rings A and X have the same meanings as the rings A and X of Formula (1) described above; the average inter-unit distance of the ring A is 1.42 Å or less; and the symbol * represents a bonding position for the repeating unit.

3. The thermoelectric conversion element according to claim 1,
wherein the ring structure of the ring A is a ring structure represented by arty one of the following Formulae (3) to (8), and 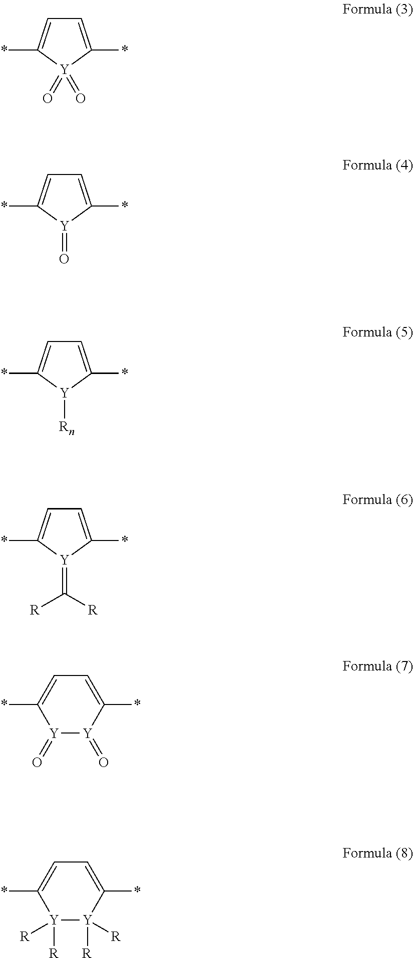
in Formulae (3) to (8), each Y independently represents an atom selected from the group consisting of a carbon atom, a sulfur atom, a nitrogen atom, a phosphorus atom, and a silicon atom; two Y's in Formulae (7) and (8) may be identical or different; n represents an integer of 1 or more; RP represents an alkyl group or an aryl group; in a case in which n represents an integer of 2 or more in Formula (5), and in the case of Formula (6) and Formula (8), plural R's may be identical or different; and the symbol * represents a bonding position for the ring A.

4. The thermoelectric conversion element according to claim 2, wherein the ring B is a benzene ring or a 5-membered or 6-membered aromatic heterocyclic ring.

5. The thermoelectric conversion element according to claim 1, wherein the polymer compound has at least one repeating unit selected from the group consisting of an ethenylene group, an ethynylene group, an arylene group, and a heteroarylene group.

6. The thermoelectric conversion element according to claim 1, wherein the thermoelectric conversion layer contains at least one polymer binder selected from a conjugated polymer binder and a non-conjugated polymer binder.

7. The thermoelectric conversion element according to claim 1, wherein the electroconductive nanomaterial is a carbon nanomaterial or a metal nanomaterial.

8. The thermoelectric conversion element according to claim 1, wherein the electroconductive nanomaterial is at least one material selected from the group consisting of carbon nanotubes, carbon nanofibers, graphite, graphene, carbon nanoparticles, and metal nanowires.

9. The thermoelectric conversion element according to claim 1, wherein the electroconductive nanomaterial is the carbon nanotube.

10. The electroconductive conversion element according to claim 1, wherein the thermoelectric conversion layer contains a dopant.

11. The thermoelectric conversion element according to claim 1, wherein the substrate has flexibility.

12. The thermoelectric conversion element according to claim 1, wherein the first electrode and the second electrode are each independently formed from aluminum, gold, silver, or copper.

13. An article for thermoelectric power generation, using the thermoelectric conversion element according to claim 1.

14. A power source for sensors, using the thermoelectric conversion element according to claim 1.

15. A thermoelectric conversion material for forming a thermoelectric conversion layer of a thermoelectric conversion element,
wherein the thermoelectric conversion material includes an electroconductive nanomaterial having an average length in the major axis direction of at least 5 nm, and a polymer compound having a repeating unit represented by the following Formula (1), and 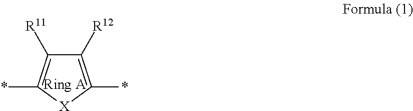
in Formula (1) ring A represents a conjugated hydrocarbon ring or a conjugated heterocyclic ring; X represents a group having one or two or more atoms selected from the group consisting of a carbon atom, an oxygen atom, a sulfur atom, a nitrogen atom, a phosphorus atom and a silicon atom, shared as ring-constituting atoms of the ring A; the average inter-unit distance of the ring A is 1.42 Å or less; R¹¹ and R¹² each independently represent a substituent, and may be bonded to each other to form a ring; and the symbol * represents a bonding position for the repeating unit.

16. The thermoelectric conversion material according to claim 15,
wherein the polymer compound has a repeating unit represented by the following Formula (2), and 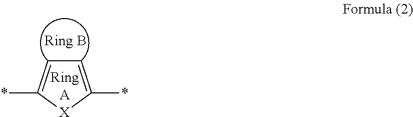
in Formula (2), ring B represents an aromatic ring; ring B may have a substituent, and may have an aromatic hydrocarbon ring or an aromatic heterocyclic ring fused thereto; rings A and X have the same meanings as the rings A and X of Formula (1) described above; the average inter-unit distance of the ring A is 1.42 Å or less; and the symbol * represents a bonding position for the repeating unit.

17. The thermoelectric conversion material according to claim 16, wherein the ring B is a benzene ring or a 5-membered or 6-membered aromatic heterocyclic ring.

18. The thermoelectric conversion material according to claim 15, containing at least one polymer binder selected from a conjugated polymer binder and a non-conjugated polymer binder.

19. The thermoelectric conversion material according to claim 15, containing an organic solvent.

20. The thermoelectric conversion material according to claim 19, obtained by dispersing the electroconductive nanomaterial in the organic solvent.
